(19) United States
(12) Patent Application Publication
(10) Pub. No.: US 2025/0294973 A1
(43) Pub. Date: Sep. 18, 2025

(54) DISPLAY DEVICE, MOTHER SUBSTRATE AND MANUFACTURING METHOD OF DISPLAY DEVICE

(71) Applicant: Japan Display Inc., Tokyo (JP)

(72) Inventors: Keisuke IZUMI, Tokyo (JP); Hiroshi TABATAKE, Tokyo (JP); Hideyuki TAKAHASHI, Tokyo (JP); Sho YANAGISAWA, Tokyo (JP); Tomokazu ISHIKAWA, Tokyo (JP)

(73) Assignee: Japan Display Inc., Tokyo (JP)

(21) Appl. No.: 19/078,402

(22) Filed: Mar. 13, 2025

(30) Foreign Application Priority Data
Mar. 15, 2024 (JP) 2024-041113

(51) Int. Cl. H10K 59/122; H10K 59/80

(52) U.S. Cl. CPC H10K 59/122; H10K 59/873

(57) ABSTRACT

According to one embodiment, a display device includes a first inorganic insulating layer provided over a display area and a surrounding area, an organic insulating layer on the first inorganic insulating layer, a second inorganic insulating layer on the organic insulating layer, a display element, a first sealing layer, surrounding partitions provided in the surrounding area, and a second sealing layer provided over the display area and the surrounding area. The organic insulating layer has a first penetration portion in the surrounding area. Each of the surrounding partitions has a first lower portion provided in the first penetration portion and a first upper portion provided on the first lower portion, and is covered with the second sealing layer.

### CROSS-REFERENCE TO RELATED APPLICATION

This application is based upon and claims the benefit of priority from Japanese Patent Application No. 2024-041113, filed Mar. 15, 2024, the entire contents of which are incorporated herein by reference.

### FIELD

Embodiments described herein relate generally to a display device, a mother substrate and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is the schematic cross-sectional view of the display device DSP along the A-B line of FIG. 2.

FIG. 4 is a plan view showing an example of the shape of an insulating layer 12 in the display device DSP.

FIG. 5 is a plan view showing an example of the shape of a sealing layer 14 in the display device DSP.

FIG. 6 is a plan view showing an example of a mother substrate 100.

FIG. 7 is a plan view showing an example of the mother substrate 100.

FIG. 8 is a plan view showing a configuration example of a pad PD.

FIG. 9 is the schematic cross-sectional view of the mother substrate 100 along the G-H line of FIG. 6.

FIG. 10 is the schematic cross-sectional view of a display panel PNL along the C-D line of FIG. 5.

FIG. 11 is a cross-sectional view showing a configuration example of area 100A of each of the mother substrate 100 shown in FIG. 9 and the display panel PNL shown in FIG. 10.

FIG. 12 is a cross-sectional view showing another configuration example of area 100A of each of the mother substrate 100 shown in FIG. 9 and the display panel PNL shown in FIG. 10.

FIG. 13 is a cross-sectional view showing a configuration example of another area of each of the mother substrate 100 shown in FIG. 9 and the display panel PNL shown in FIG. 10.

FIG. 14 is a cross-sectional view showing a configuration example of the pad PD along the E-F line of FIG. 8.

FIG. 15 is a cross-sectional view showing another configuration example of the pad PD along the E-F line of FIG. 8.

FIG. 16 is a plan view showing a configuration example of surrounding partitions 7 in a penetration portion 12T.

FIG. 17 is a cross-sectional view showing a configuration example of a surrounding partition 7A and a surrounding partition 7B along the I-J line of FIG. 16.

FIG. 18 is a cross-sectional view showing another configuration example of the surrounding partition 7A and the surrounding partition 7B along the I-J line of FIG. 16.

FIG. 19 is a plan view showing another configuration example of the surrounding partitions 7 in the penetration portion 12T.

FIG. 20 is a diagram for explaining the manufacturing method of the display device DSP.

FIG. 21 is a diagram for explaining the manufacturing method of the display device DSP.

FIG. 22 is a diagram for explaining the manufacturing method of the display device DSP.

FIG. 23 is a diagram for explaining the manufacturing method of the display device DSP.

FIG. 24 is a diagram for explaining the manufacturing method of the display device DSP.

FIG. 25 is a diagram for explaining the manufacturing method of the display device DSP.

FIG. 26 is a diagram for explaining the manufacturing method of the display device DSP.

FIG. 27 is a diagram for explaining the manufacturing method of the display device DSP.

FIG. 28 is a diagram for explaining the manufacturing method of the display device DSP.

FIG. 29 is a diagram for explaining the manufacturing method of the display device DSP.

FIG. 30 is a diagram for explaining the manufacturing method of the display device DSP.

FIG. 31 is a diagram for explaining the manufacturing method of the display device DSP.

FIG. 32 is a diagram for explaining the manufacturing method of the display device DSP.

FIG. 33 is a diagram for explaining the manufacturing method of the display device DSP.

FIG. 34 is a diagram for explaining the manufacturing method of the display device DSP.

FIG. 35 is a diagram for explaining the manufacturing method of the display device DSP.

### DETAILED DESCRIPTION

Embodiments described herein aim to provide a display device, a mother substrate and a manufacturing method of a display device such that the reduction in reliability can be prevented.

In general, according to one embodiment, a display device comprises a substrate, a first inorganic insulating layer provided over a display area which displays an image and a surrounding area located on an external side relative to the display area above the substrate, an organic insulating layer provided on the first inorganic insulating layer, a second inorganic insulating layer provided on the organic insulating layer, a display element provided in the display area, a first sealing layer which is formed of an inorganic insulating material and covers the display element, a plurality of surrounding partitions provided in the surrounding area, and a second sealing layer formed of an inorganic insulating material and provided over the display area and the surrounding area. The organic insulating layer has a first penetration portion in the surrounding area. Each of the surrounding partitions has a first lower portion provided in the first penetration portion and a first upper portion provided on the first lower portion, and is covered with the second sealing layer.

According to another embodiment, a mother substrate comprises a panel portion which has a display area displaying an image and a surrounding area located on an external side relative to the display area, a margin portion located on an external side relative to the panel portion, a first inorganic insulating layer provided over the panel portion and the margin portion, an organic insulating layer provided on the first inorganic insulating layer, a second inorganic insulating layer provided on the organic insulating layer, a display element provided in the display area, a first sealing layer which is formed of an inorganic insulating material and covers the display element, a plurality of surrounding partitions provided in the margin portion, and a second sealing layer formed of an inorganic insulating material and provided over the panel portion and the margin portion. The organic insulating layer has a first penetration portion in the margin portion. Each of the surrounding partitions has a first lower portion provided in the first penetration portion and a first upper portion provided on the first lower portion, and is covered with the second sealing layer.

According to yet another embodiment, a manufacturing method of a display device comprises preparing a processing substrate comprising a first inorganic insulating layer over a display area which displays an image and a surrounding area located on an external side relative to the display area, an organic insulating layer located on the first inorganic insulating layer, a second inorganic insulating layer located on the organic insulating layer, a display element located in the display area, a plurality of surrounding partitions located in the surrounding area, and a first sealing layer which covers the display element and is formed such that the surrounding partitions are exposed, and forming a second sealing layer over the display area and the surrounding area by an inorganic insulating material. Patterning for forming the organic insulating layer includes a process of forming a first penetration portion in the surrounding area. Each of the surrounding partitions has a first lower portion provided in the first penetration portion and a first upper portion provided on the first lower portion, and is covered with the second sealing layer.

The embodiments can provide a display device, a mother substrate and a manufacturing method of a display device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

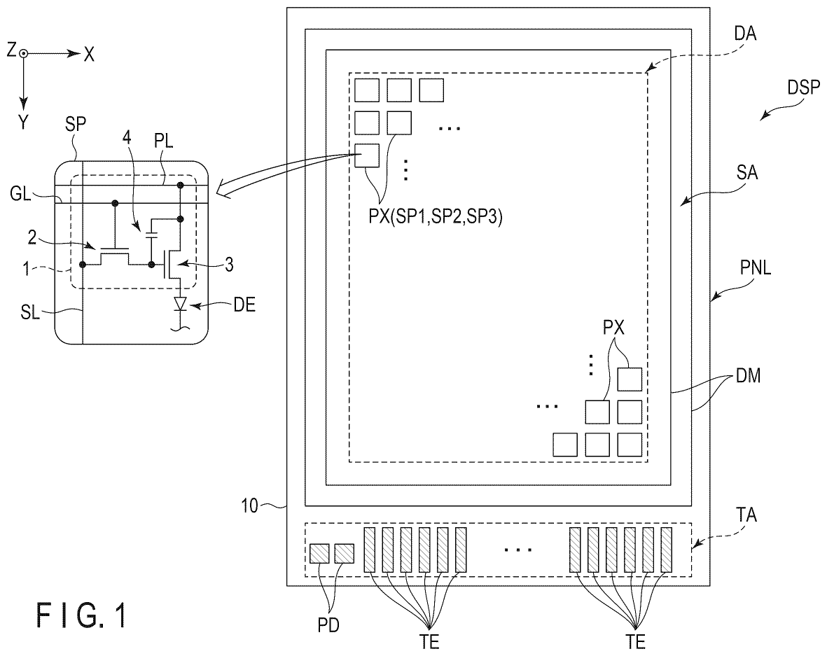

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA has a terminal area TA. The terminal area TA has terminals TE and pads PD which are unidirectionally arranged. In the example shown in the figure, the terminals TE are arranged in the first direction X. Each of the terminals TE extends in the second direction Y. However, the configuration is not limited to this example. For example, these terminals TE are electrically connected to a flexible printed circuit or an IC chip. The pads PD are electrically connected to, for example, an inspection device. It should be noted that the pads PD may be omitted in the display device DSP.

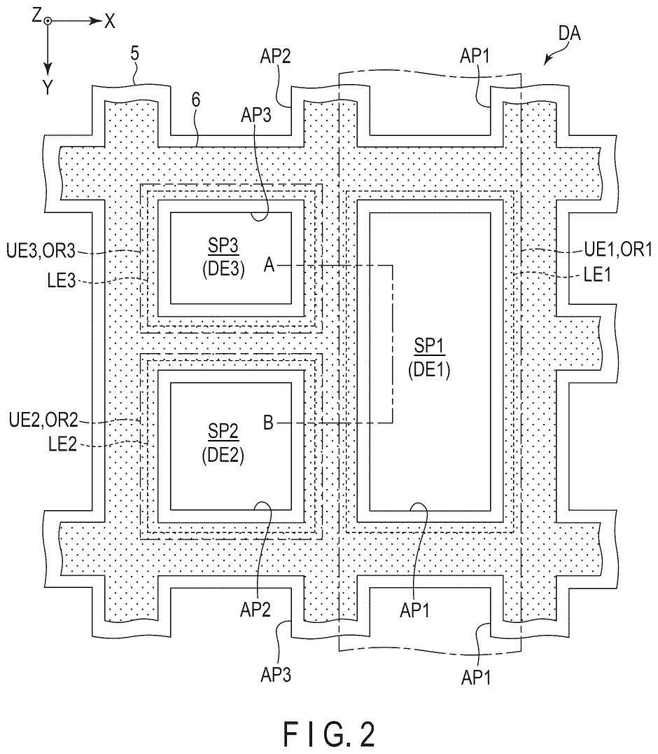

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The lower electrode LE1, the organic layer OR1 and the upper electrode UE1 constituting the display element DE1 are surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The lower electrode LE2, the organic layer OR2 and the upper electrode UE2 constituting the display element DE2 are surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The lower electrode LE3, the organic layer OR3 and the upper electrode UE3 constituting the display element DE3 are surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, the organic layers and the upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

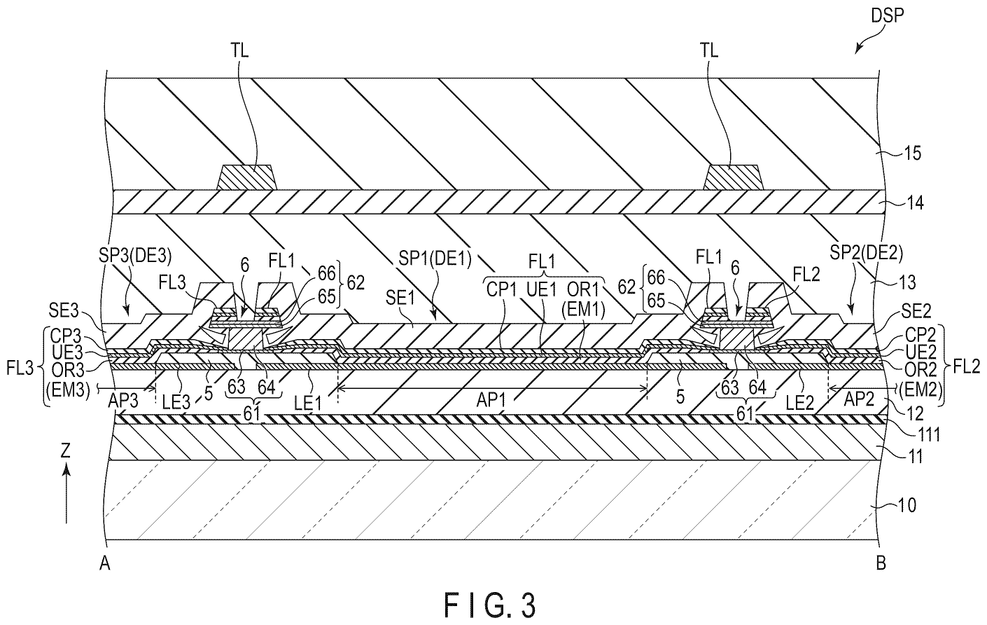

FIG. 3 is the schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. An inorganic insulating layer 111 included in the circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 has a conductive lower portion 61 provided on the inorganic insulating layer 5, and an upper portion 62 provided on the lower portion 61.

In the example shown in the figure, the lower portion 61 has a bottom layer 63 provided on the inorganic insulating layer 5, and a stem layer 64 provided between the bottom layer 63 and the upper portion 62. The bottom layer 63 is thinner than the stem layer 64. The bottom layer 63 has a width greater than that of the stem layer 64. The both end portions of the bottom layer 63 protrude from the side surfaces of the stem layer 64.

The upper portion 62 has a thin film 65 provided on the stem layer 64 and a thin film 66 provided on the thin film 65. The upper portion 62 has a width greater than that of the stem layer 64. The both end portions of the upper portion 62 protrude from the side surfaces of the stem layer 64. In this specification, the side surfaces of the stem layer 64 are assumed to be, of the stem layer 64, the surfaces which extend between the bottom layer 63 and the upper portion 62.

In the example shown in the figure, the upper portion 62 has a width greater than that of the bottom layer 63. It should be noted that the bottom layer 63 may have a width greater than that of the upper portion 62.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

It should be noted that the contact between each of the upper electrodes UE1, UE2 and UE3 and the lower portion 61 includes a case where each of the upper electrodes UE1, UE2 and UE3 is directly in contact with the upper surface of the bottom layer 63 and a case where each of the upper electrodes UE1, UE2 and UE3 is directly in contact with the upper surface of the bottom layer 63 and is further directly in contact with a side surface of the stem layer 64. In this specification, the upper surface of the bottom layer 63 is assumed to include, of the bottom layer 63, the surface which is directly in contact with the stem layer 64, and the surface which protrudes from the stem layer 64 and faces the upper portion 62.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1. Thus, the sealing layer SE1 is in contact with the stem layer 64 and the upper portion 62 of the partition 6 which surrounds the display element DE1.

The sealing layer SE2 is provided on the cap layer CP2, is in contact with the partition 6 and continuously covers each member of subpixel SP2. Thus, the sealing layer SE2 is in contact with the stem layer 64 and the upper portion 62 of the partition 6 which surrounds the display element DE2.

The sealing layer SE3 is provided on the cap layer CP3, is in contact with the partition 6 and continuously covers each member of subpixel SP3. Thus, the sealing layer SE3 is in contact with the stem layer 64 and the upper portion 62 of the partition 6 which surrounds the display element DE3.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

In the example shown in the figure, part of the stacked film FL1 is located on the partition 6 around subpixel SP1 and spaced apart from the stacked film FL1 located in the aperture AP1 (in other words, the portion which constitutes the display element DE1).

Similarly, part of the stacked film FL2 is located on the partition 6 around subpixel SP2 and spaced apart from the stacked film FL2 located in the aperture AP2 (in other words, the portion which constitutes the display element DE2).

Similarly, part of the stacked film FL3 is located on the partition 6 around subpixel SP3 and spaced apart from the stacked film FL3 located in the aperture AP3 (in other words, the portion which constitutes the display element DE3).

It should be noted that the stacked films FL1, FL2 and FL3 located on the partition 6 may be omitted in some cases. In these cases, a cavity is formed between the sealing layers SE1, SE2 and SE3 and the partition 6.

Each of the end portions of the sealing layers SE1, SE2 and SE3 is located above the partition 6. In the example shown in the figure, the stacked film FL1 and the sealing layer SE1 located on the partition 6 between subpixels SP1 and SP2 are spaced apart from the stacked film FL2 and the sealing layer SE2 located on this partition 6. The stacked film FL1 and the sealing layer SE1 located on the partition 6 between subpixels SP1 and SP3 are spaced apart from the stacked film FL3 and the sealing layer SE3 located on this partition 6.

The partition 6 and the sealing layers SE1, SE2 and SE3 are covered with a resin layer 13. When cavities are formed between the sealing layers SE1, SE2 and SE3 and the partition 6, these cavities are filled with the resin layer 13. The resin layer 13 is covered with a sealing layer 14. Lines TL are provided on the sealing layer 14 and are located, for example, immediately above the partition 6. These lines TL function as, for example, sensor lines for detecting an object which approaches the display device DSP. The sealing layer 14 and the wiring lines TL are covered with a resin layer 15.

Each of the inorganic insulating layer 111, the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to each of the upper electrodes UE1, UE2 and UE3. The bottom layer 63 is formed of, for example, a titanium-based material such as titanium or a titanium compound. The stem layer 64 is formed of a material which is different from the materials of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The thin film 65 is formed of, for example, a titanium-based material such as titanium or a titanium compound. The thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The wiring lines TL are formed of, for example, a metal material such as aluminum, titanium or molybdenum. For example, each line TL is a multilayer body which includes an aluminum layer between a pair of titanium layers.

The circuit layer 11, the insulating layer 12 and the inorganic insulating layer 5 shown in the figure are provided over the display area DA and the surrounding area SA.

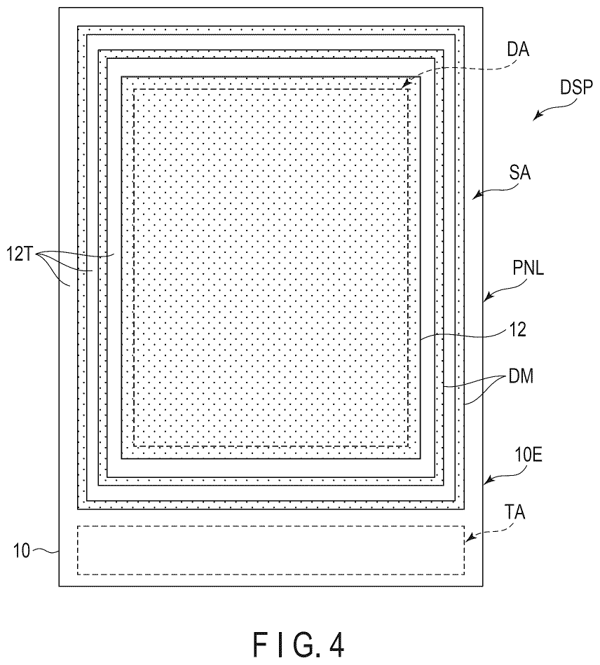

FIG. 4 is a plan view showing an example of the shape of the insulating layer 12 in the display device DSP. FIG. 4 shows configurations necessary for explanation and omits the details of the terminal area TA.

The insulating layer 12 overlaps the display area DA and extends to the surrounding area SA. The insulating layer 12 has a penetration portion 12T which is formed such that the base layer is exposed in the surrounding area SA. The penetration portion 12T is formed into a loop shape along an end portion 10E.

A plurality of dam portions DM are an insulating layer formed of the same material as the insulating layer 12, and may be a single-layer body or a multilayer body consisting of a plurality of insulating layers. The dam portions DM are provided in the surrounding area SA and formed into a loop shape which surrounds the insulating layer 12. In the example shown in the figure, the number of dam portions DM is two. However, the number of dam portions DM may be three or greater.

In the example shown in the figure, each of the penetration portion 12T and the dam portions DM is formed into the shape of a rectangular frame. However, they may be formed into another polygonal shape, a circular shape or an oval shape.

The dam portion (inner dam portion) DM which is adjacent to the insulating layer 12 is spaced apart from the insulating layer 12. The dam portions DM are provided at intervals. The penetration portion 12T includes the area located between the insulating layer 12 and the inner dam portion DM, the area located between the dam portions DM which are adjacent to each other, and the area located between the outermost dam portion (outer dam portion) DM and the end portion 10E of the substrate 10.

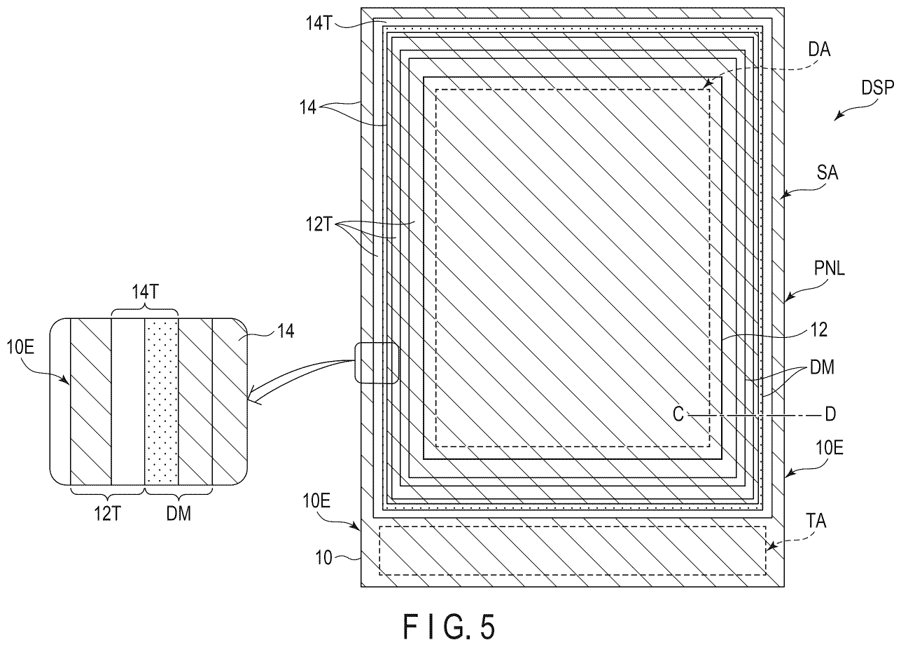

FIG. 5 is a plan view showing an example of the shape of the sealing layer 14 in the display device DSP. FIG. 5 shows configurations necessary for explanation and omits the details of the terminal area TA.

The sealing layer 14 is provided over the display area DA and the surrounding area SA. The sealing layer 14 has a penetration portion 14T which is formed such that the base layer is exposed in the surrounding area SA. The penetration portion 14T is formed into a loop shape which surrounds the display area DA. In the example shown in the figure, the penetration portion 14T is located between the outer dam portion DM and the end portion 10E of the substrate 10, and overlaps the outer dam portion DM and the outermost penetration portion 12T in plan view. The sealing layer 14 overlaps the insulating layer 12, the area located between the insulating layer 12 and the inner dam portion DM and the area located between the dam portions DM which are adjacent to each other.

In the example shown in the figure, the penetration portion 14T is formed into the shape of a rectangular frame. However, it may be formed into another polygonal shape, a circular shape or an oval shape.

Now, this specification explains a mother substrate 100 for a display device (hereinafter, simply referred to as a mother substrate 100) for manufacturing a plurality of display devices DSP in a lump.

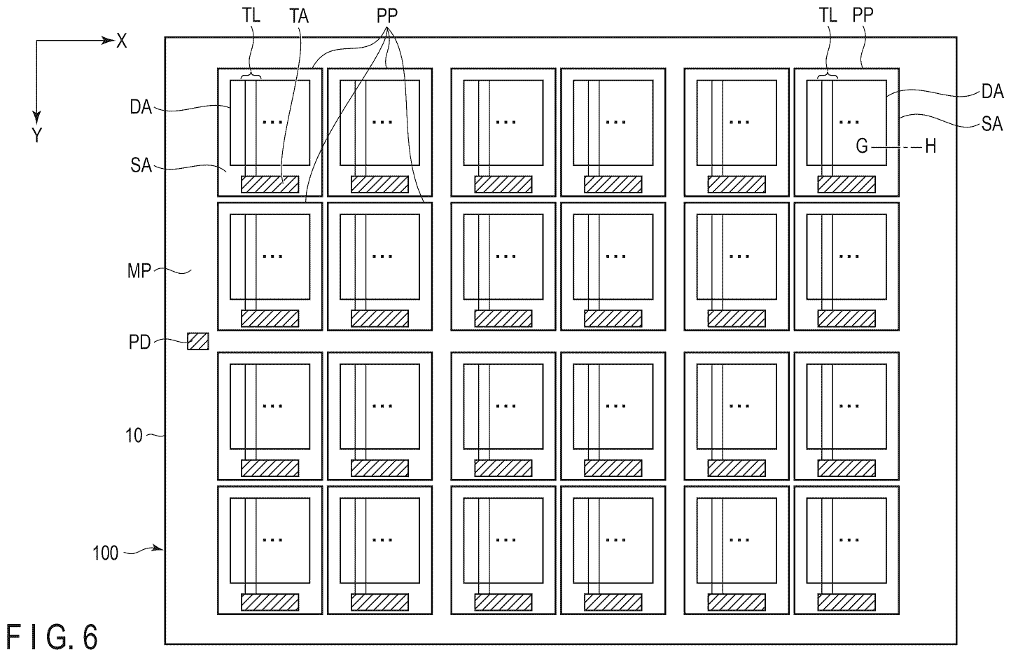

FIG. 6 is a plan view showing an example of the mother substrate 100.

The mother substrate 100 comprises a plurality of panel portions PP and a margin portion MP provided on an external side relative to these panel portions PP on a large substrate 10. The large substrate 10 is formed into, for example, a rectangular shape. Each of the panel portions PP is extracted by dividing the mother substrate 100 along a cut line.

Each of the extracted panel portions PP corresponds to, for example, the display panel PNL shown in FIG. 1 and comprises the display area DA and the surrounding area SA. The surrounding area SA has the terminal area TA in which the terminals TE and the pads PD shown in FIG. 1 are provided. The wiring lines TL are provided in the display area DA, are drawn to the surrounding area SA and are electrically connected to the terminals TE included in the terminal area TA.

The margin portion MP comprises, for example, a plurality of pads PD electrically connected to a test element group etc.

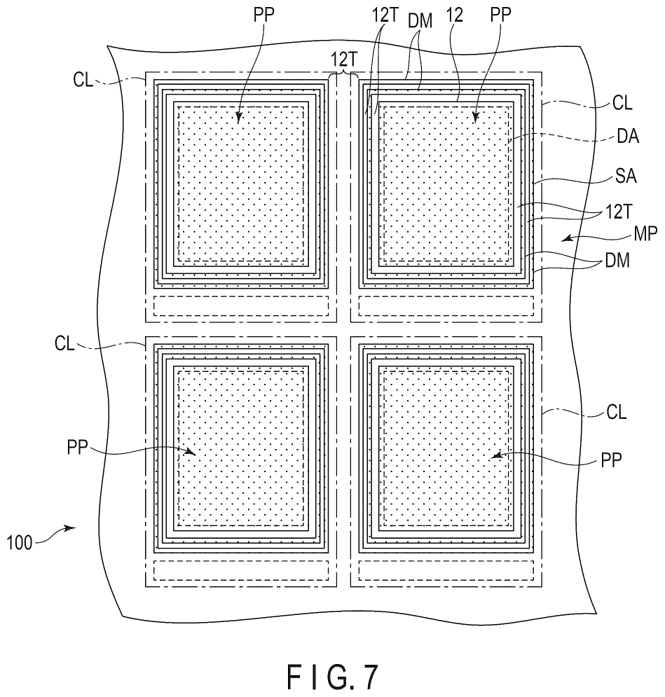

FIG. 7 is a plan view showing an example of the mother substrate 100.

The cut line CL for extracting each panel portion PP is shown by a dashed line in the figure. In each panel portion PP, the penetration portion 12T is formed in the area located between the insulating layer 12 and the dam portions DM and the area located between the dam portions which are adjacent to each other. The penetration portion 12T is located in both the panel portion PP and the margin portion MP, is formed into a loop shape which surrounds the panel portion PP and overlaps the cut line CL.

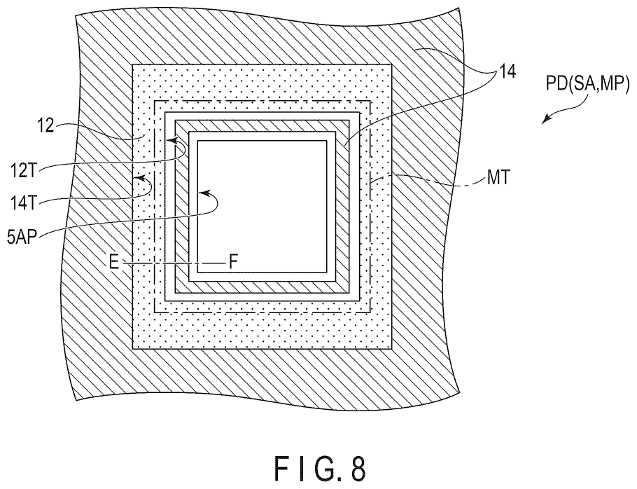

FIG. 8 is a plan view showing a configuration example of the pad PD. The pad PD shown in the figure corresponds to each pad PD of the surrounding area SA shown in FIG. 1 or each pad PD of the margin portion MP shown in FIG. 6.

The metal layer MT shown by dashed lines corresponds to the electrode of the pad PD. The metal layer MT overlaps the aperture 5AP of the inorganic insulating layer 5, the penetration portion 12T of the insulating layer 12 and the penetration portion 14T of the sealing layer 14 and is exposed from the aperture 5AP. The sealing layer 14 is partly located between the edge portion of the aperture 5AP and the edge portion of the penetration portion 12T.

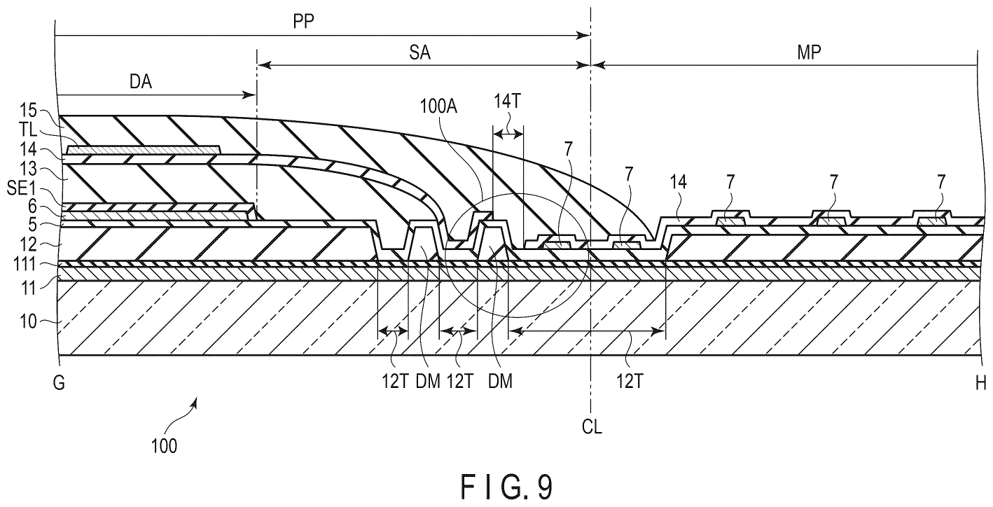

FIG. 9 is the schematic cross-sectional view of the mother substrate 100 along the G-H line of FIG. 6.

The inorganic insulating layer 111 included in the circuit layer 11 is provided over the panel portion PP and the margin portion MP. The insulating layer 12 and the dam portions DM are provided on the inorganic insulating layer 111. The inorganic insulating layer 5 is provided over the panel portion PP and the margin portion MP and covers the insulating layer 12 and the dam portions DM. In the penetration portion 12T, the inorganic insulating layer 5 is in contact with the inorganic insulating layer 111.

Although the illustration of the partition 6 is simplified in the figure, the partition 6 is provided on the inorganic insulating layer 5 in the display area DA. Although the illustration of surrounding partitions 7 is simplified in the figure, the surrounding partitions 7 are provided on the inorganic insulating layer 5 in the surrounding area SA of the panel portion PP and the margin portion MP. Some of the surrounding partitions 7 are provided in the penetration portion 12T. For example, near the cut line CL, the surrounding partitions 7 are provided in the penetration portion 12T of the surrounding area SA and the penetration portion 12T of the margin portion MP.

The sealing layer SE1 is provided on the partition 6 in the display area DA. Although not shown in FIG. 9, other sealing layers SE2 and SE3 are also provided in the display area DA. The details of the sealing layers SE1, SE2 and SE3 are as explained with reference to FIG. 3.

The resin layer 13 is provided in the display area DA and is also provided in the surrounding area SA. The resin layer 13 has an end portion near the dam portion DM.

The sealing layer 14 is provided over the panel portion PP and the margin portion MP. The sealing layer 14 covers the resin layer 13 in the panel portion PP and is in contact with the inorganic insulating layer 5 in the penetration portion 12T. In the example shown in the figure, as part of the penetration portion 12T, the sealing layer 14 is in contact with the inorganic insulating layer 5 between the dam portions DM which are adjacent to each other. In other words, a multilayer body in which the inorganic insulating layer 111, the inorganic insulating layer 5 and the sealing layer 14 are stacked in order is formed, and further, no organic insulating material is interposed between them. This multilayer body is formed so as to surround the display area DA. This multilayer body forms a moisture blocking area which blocks the path of moisture which could enter the display area DA from the outside through the organic insulating material.

The penetration portion 14T of the sealing layer 14 is located in the surrounding area SA, is formed on a side which is closer to the cut line CL than the moisture blocking area, and is formed such that the inorganic insulating layer 5 is exposed. In the example shown in the figure, the penetration portion 14T overlaps the slope of the dam portion DM. The sealing layer 14 further covers the partitions 7 in the surrounding area SA and the margin portion MP.

The wiring line TL is provided on the sealing layer 14 in the display area DA. The resin layer 15 is provided in the panel portion PP, covers the sealing layer 14 and the wiring line TL, and has an end portion on an external side relative to the resin layer 13. In the example shown in the figure, the resin layer 15 is provided in the margin portion MP as well beyond the cut line CL and has an end portion in the penetration portion 12T. In the penetration portion 14T, the resin layer 15 is in contact with the inorganic insulating layer 5. The resin layer 15 overlaps the surrounding partitions 7 located in the penetration portion 12T. In a case where the resin layer 15 has an end portion near the cut line CL, the resin layer 15 does not overlap the partitions 7 located on the margin portion MP side relative to the cut line CL.

In this configuration example, even if a crack is generated in the sealing layer 14 near the cut line CL when the mother substrate 100 is divided along the cut line CL, the expansion of the crack can be prevented in the penetration portion 14T. Therefore, this configuration example prevents the crack from expanding to the moisture blocking area which is formed in the penetration portion 12T between the penetration portion 14T and the display area DA. Thus, the moisture intrusion into the display area DA is prevented, and the reduction in reliability is prevented.

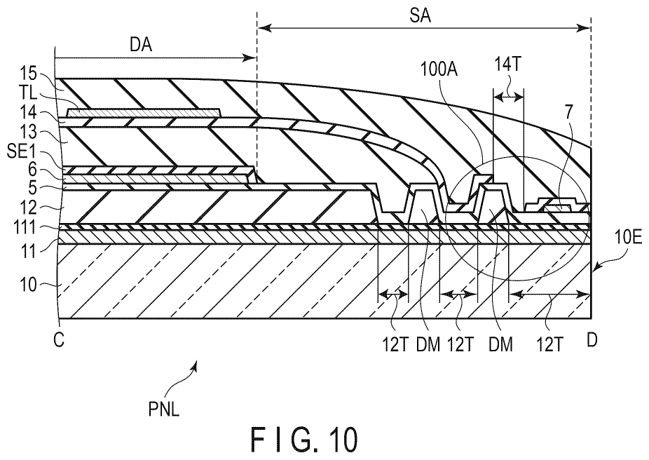

FIG. 10 is the schematic cross-sectional view of the display panel PNL along the C-D line of FIG. 5.

The end portion 10E of the substrate 10 in the figure corresponds to the location of the cut line CL of the mother substrate 100 shown in FIG. 9. The penetration portion 12T is formed in the surrounding area SA. The inorganic insulating layer 5 is in contact with the inorganic insulating layer 111 in the penetration portion 12T. The surrounding partition 7 is provided on the inorganic insulating layer 5 in the penetration portion 12T. The sealing layer 14 is in contact with the inorganic insulating layer 5 and covers the surrounding partition 7 in the penetration portion 12T. The penetration portion 14T of the sealing layer 14 is located in the surrounding area SA, overlaps the slope of the dam portion DM and is formed such that the inorganic insulating layer 5 is exposed. A moisture blocking area which is the multilayer body of the inorganic insulating layer 111, the inorganic insulating layer 5 and the sealing layer 14 is formed in the penetration portion 12T between the penetration portion 14T and the display area DA. The resin layer 15 is in contact with the inorganic insulating layer 5 in the penetration portion 14T.

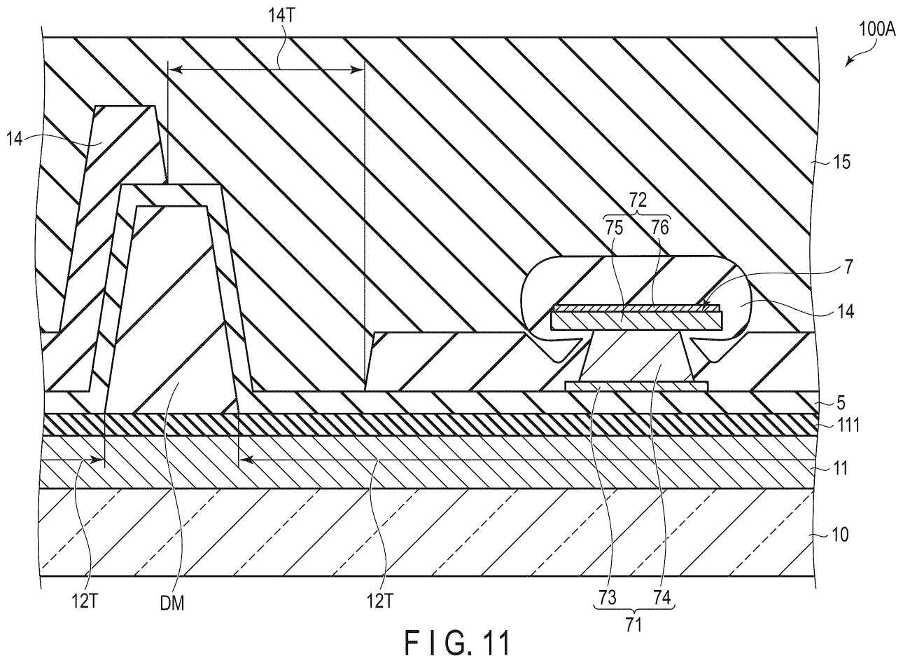

FIG. 11 is a cross-sectional view showing a configuration example of area 100A of each of the mother substrate 100 shown in FIG. 9 and the display panel PNL shown in FIG. 10.

The surrounding partition 7 has a lower portion 71 provided on the inorganic insulating layer 5 in the penetration portion 12T, and an upper portion 72 provided on the lower portion 71. The lower portion 71 has a bottom layer 73 provided on the inorganic insulating layer 5, and a stem layer 74 provided between the bottom layer 73 and the upper portion 72. The upper portion 72 has a thin film 75 provided on the stem layer and a thin film 76 provided on the thin film 75.

The bottom layer 73 is thinner than the stem layer 74. The bottom layer 73 has a width greater than that of the stem layer 74. The both end portions of the bottom layer 73 protrude from the side surfaces of the stem layer 74. The upper portion 72 has a width greater than that of the stem layer 74. The both end portions of the upper portion 72 protrude from the side surfaces of the stem layer 74. In the example shown in the figure, the upper portion 72 has a width greater than that of the bottom layer 73. It should be noted that the bottom layer 73 may have a width greater than that of the upper portion 72.

The surrounding partition 7 can be formed in the same process as the partition 6 described above. In this case, the bottom layer 73 is formed of the same material as the bottom layer 63. The stem layer 74 is formed of the same material as the stem layer 64. The thin film 75 if formed of the same material as the thin film 65. The thin film 76 is formed of the same material as the thin film 66.

The sealing layer 14 is in contact with the bottom layer 73, the stem layer 74 and the upper portion 72 and covers the entire surrounding partition 7. Since the sealing layer 14 covers the surrounding partition 7 in this manner, the unevenness caused by the sectional shape of the surrounding partition 7 is eased compared to that before the formation of the sealing layer 14.

In addition, as the penetration portion 14T of the sealing layer 14 overlaps the steep slope of the dam portion DM, the stress which acts on the sealing layer 14 near the slop is reduced, and thus, the removal of the sealing layer 14 from the inorganic insulating layer 5 can be prevented.

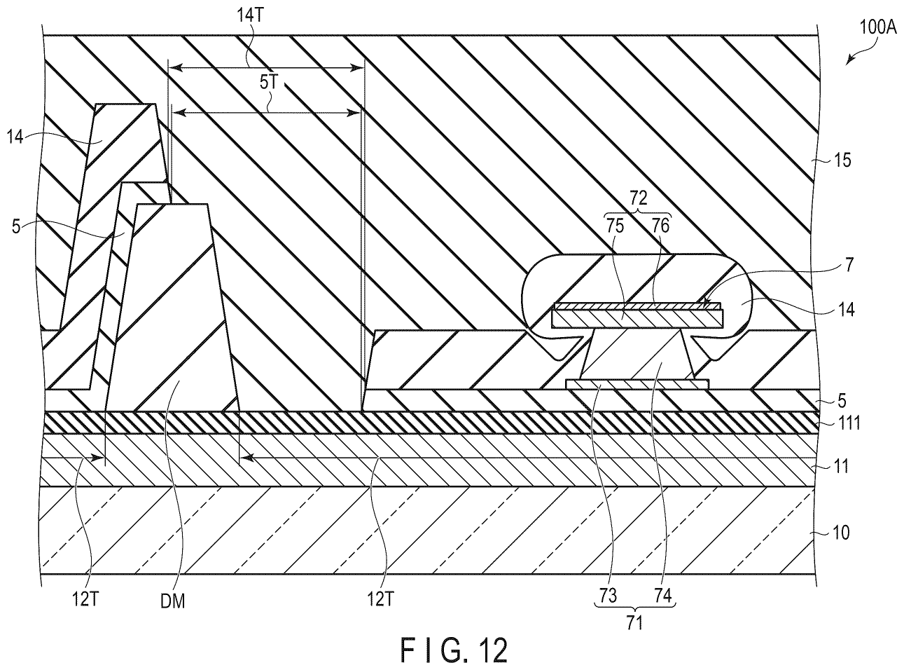

FIG. 12 is a cross-sectional view showing another configuration example of area 100A of each of the mother substrate 100 shown in FIG. 9 and the display panel PNL shown in FIG. 10.

The configuration example shown in FIG. 12 is different from that shown in FIG. 11 in respect that the inorganic insulating layer 5 has a penetration portion 5T. The penetration portion 5T overlaps the penetration portion 14T. Thus, the slope of the dam portion DM is exposed from the inorganic insulating layer 5 in the penetration portion 5T. The penetration portion 5T overlaps the penetration portion 12T. Thus, the inorganic insulating layer 111 is exposed from the inorganic insulating layer 5 in the penetration portion 5T.

In the penetration portion 5T, the resin layer 15 is in contact with the dam portion DM and is also in contact with the inorganic insulating layer 111.

Even in this configuration example, in a manner similar to that of the configuration example shown in FIG. 11, as the surrounding partition 7 is covered with the sealing layer 14, the unevenness caused by the sectional shape of the surrounding partition 7 is eased.

In addition, as the penetration portion 5T of the inorganic insulating layer 5 overlaps the steep slope of the dam portion DM, the stress which acts on the inorganic insulating layer 5 near the slop is reduced, and thus, the removal of the inorganic insulating layer 5 and the sealing layer 14 from the dam portion DM and the inorganic insulating layer 111 can be prevented.

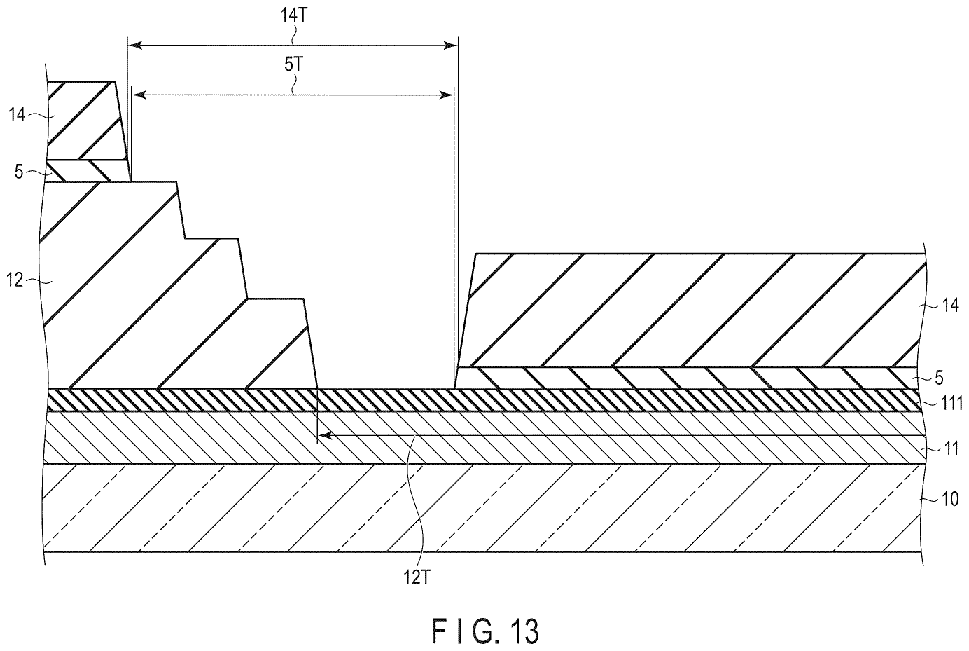

FIG. 13 is a cross-sectional view showing a configuration example of another area of each of the mother substrate 100 shown in FIG. 9 and the display panel PNL shown in FIG. 10.

The insulating layer 12 has a stepwise section in which the thickness decreases toward the penetration portion 12T. It should be noted that the insulating layer 12 shown here may be a single-layer body or may be a multilayer body consisting of a plurality of insulating layers. When the insulating layer 12 has the stepwise section shown in the figure, the inclination is eased compared to the slope of the dam portion DM shown in FIG. 11 etc. However, for example, near the intersection of the slope of the insulating layer 12 and the inorganic insulating layer 111, a stress which is relatively great is easily generated. For this reason, the configuration in which the penetration portion 5T of the inorganic insulating layer 5 and the penetration portion 14T of the sealing layer 14 overlap the slope of the insulating layer 12 can prevent the removal of the inorganic insulating layer 5 and the sealing layer 14 based on the vicinity of the intersection described above.

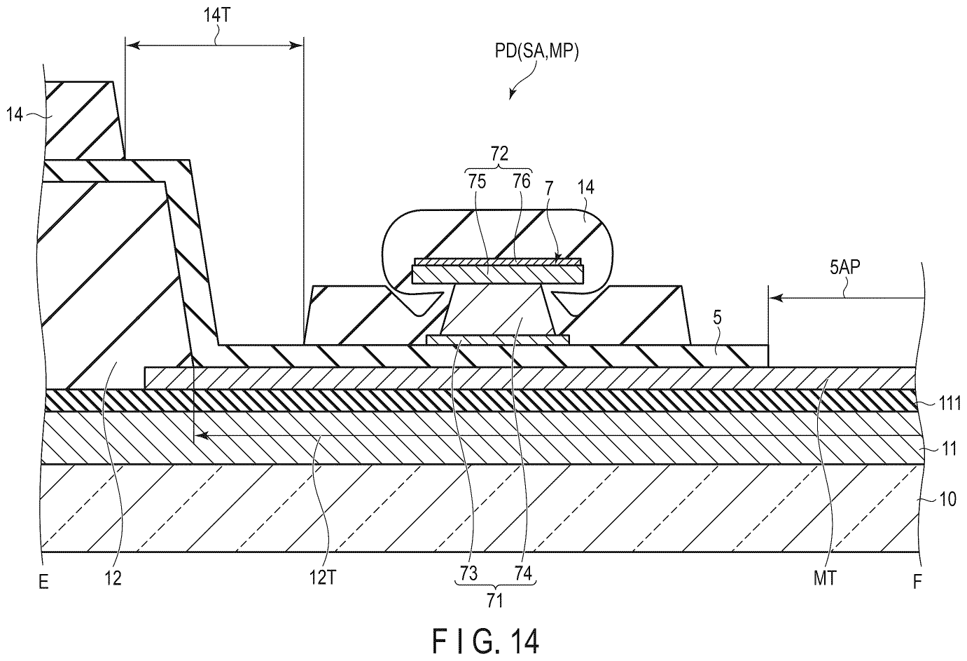

FIG. 14 is a cross-sectional view showing a configuration example of the pad PD along the E-F line of FIG. 8.

The metal layer MT is provided on the inorganic insulating layer 111. The insulating layer 12 overlaps the peripheral portion of the metal layer MT and is provided on the inorganic insulating layer 111. The penetration portion 12T of the insulating layer 12 overlaps the metal layer MT. The inorganic insulating layer 5 covers the insulating layer 12 and is in contact with the metal layer MT in the penetration portion 12T. The inorganic insulating layer 5 has the aperture 5AP from which the metal layer MT is exposed.

The surrounding partition 7 is provided on the inorganic insulating layer 5 in the penetration portion 12T. The sealing layer 14 is in contact with the bottom layer 73, the stem layer 74 and the upper portion 72 and covers the entire surrounding partition 7. The penetration portion 14T of the sealing layer 14 overlaps the slope of the insulating layer 12 and is formed such that the inorganic insulating layer 5 is exposed.

Even in this configuration example, as the surrounding partition 7 is covered with the sealing layer 14, the unevenness caused by the sectional shape of the surrounding partition 7 is eased.

In addition, as the penetration portion 14T of the sealing layer 14 overlaps the steep slope of the insulating layer 12, the stress which acts on the sealing layer 14 near the slop is reduced, and thus, the removal of the sealing layer 14 from the inorganic insulating layer 5 can be prevented.

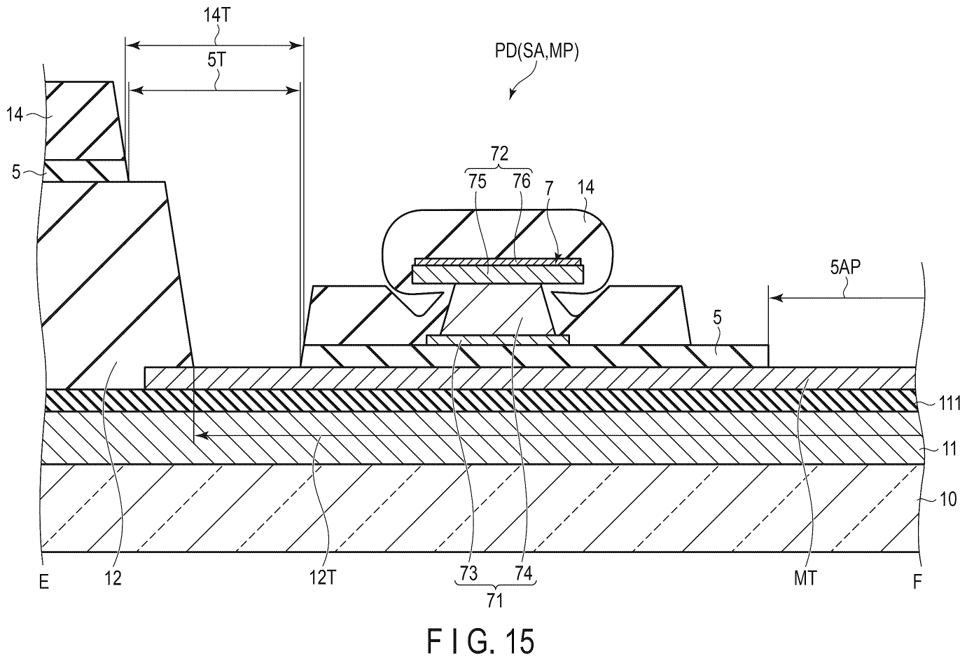

FIG. 15 is a cross-sectional view showing another configuration example of the pad PD along the E-F line of FIG. 8.

The configuration example shown in FIG. 15 is different from that shown in FIG. 14 in respect that the inorganic insulating layer 5 has a penetration portion 5T. The penetration portion 5T overlaps the penetration portion 14T. Thus, the slope of the insulating layer 12 is exposed from the inorganic insulating layer 5 in the penetration portion 5T. The penetration portion 5T overlaps the penetration portion 12T. Thus, the inorganic insulating layer 111 is exposed from the inorganic insulating layer 5 in the penetration portion 5T.

Even in this configuration example, in a manner similar to that of the configuration example shown in FIG. 14, as the surrounding partition 7 is covered with the sealing layer 14, the unevenness caused by the sectional shape of the surrounding partition 7 is eased.

In addition, as the penetration portion 5T of the inorganic insulating layer 5 overlaps the steep slope of the insulating layer 12, the stress which acts on the inorganic insulating layer 5 near the slop is reduced, and thus, the removal of the inorganic insulating layer 5 and the sealing layer 14 from the insulating layer 12 and the inorganic insulating layer 111 can be prevented.

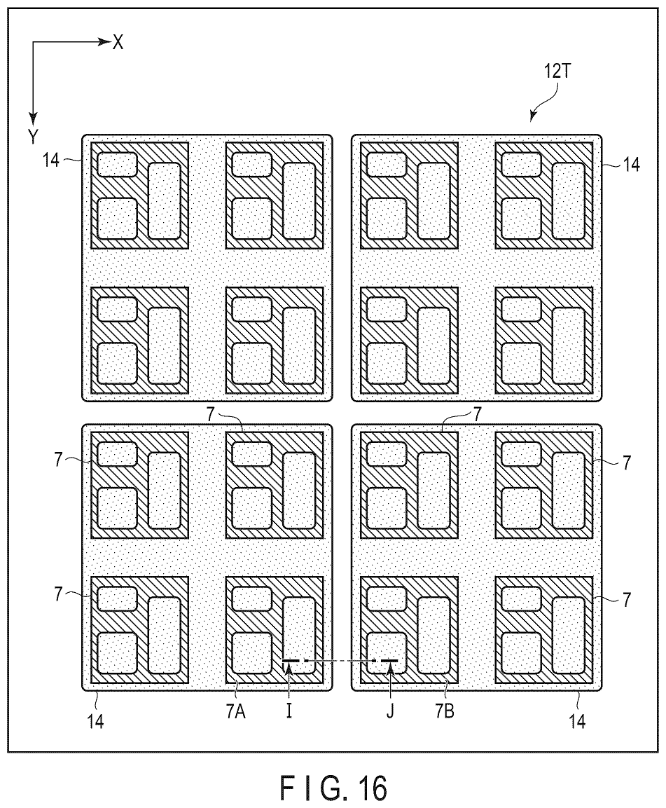

FIG. 16 is a plan view showing a configuration example of the surrounding partitions 7 in the penetration portion 12T.

Each of the surrounding partitions 7 is formed into a grating shape in plan view. For example, each surrounding partition 7 is formed with a pattern similar to that of the grating-shaped partition 6 shown in FIG. 2. The surrounding partitions 7 are arranged in the first direction X and the second direction Y and are spaced apart from each other. These surrounding partitions 7 are covered with the sealing layer 14. It should be noted that the planar shape of each surrounding partition 7 is not limited to the grating shape shown in the figure and may be a linear shape, an L-shape, an arcuate shape and the like.

In the example shown in the figure, the sealing layer 14 is divided into pieces, and each portion into which the sealing layer 14 is divided is formed so as to cover four surrounding partitions 7. For example, a gap of approximately 5 to 10 μm is formed between the sealing layers 14 which are adjacent to each other. In the figure, surrounding partitions 7A and 7B are spaced apart from each other and are arranged in the first direction X. In the sealing layer 14, the portion which covers the surrounding partition 7A is spaced apart from the portion which covers the surrounding partition 7B.

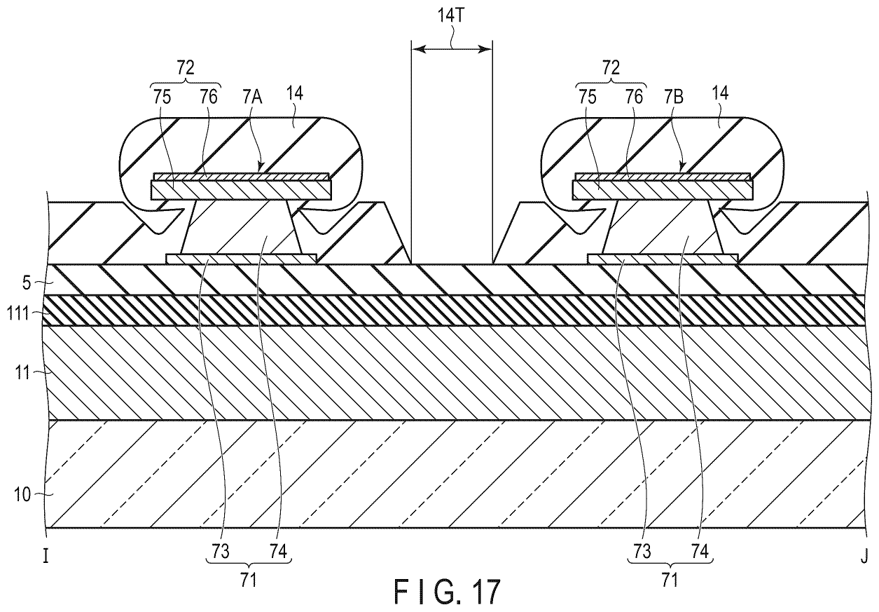

FIG. 17 is a cross-sectional view showing a configuration example of the surrounding partition 7A and the surrounding partition 7B along the I-J line of FIG. 16.

The sealing layer 14 is in contact with the bottom layer 73, the stem layer 74 and the upper portion 72 in the surrounding partition 7A. Further, the sealing layer 14 is in contact with the bottom layer 73, the stem layer 74 and the upper portion 72 in the surrounding partition 7B. The sealing layer 14 has the penetration portion 14T between the portion which covers the surrounding partition 7A and the portion which covers the surrounding partition 7B. Thus, the inorganic insulating layer 5 is exposed from the sealing layer 14 between the surrounding partition 7A and the surrounding partition 7B.

When the sealing layer 14 is divided into pieces like the configuration examples shown in FIG. 16 and FIG. 17, the stress which acts on the sealing layer 14 is reduced, and the removal of the sealing layer 14 from the inorganic insulating layer 5 can be prevented.

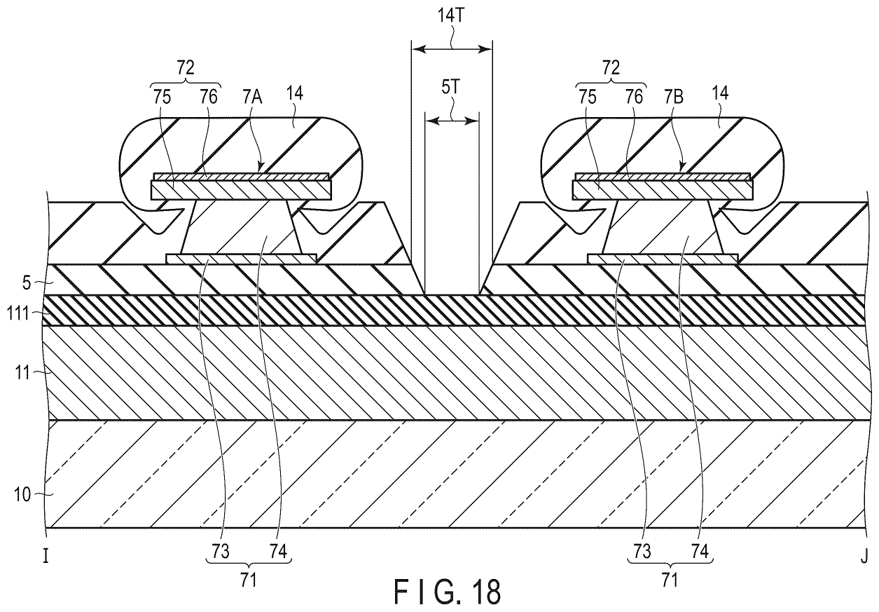

FIG. 18 is a cross-sectional view showing another configuration example of the surrounding partition 7A and the surrounding partition 7B along the I-J line of FIG. 16.

The configuration example shown in FIG. 18 is different from that shown in FIG. 17 in respect that the inorganic insulating layer 5 has a penetration portion 5T. The penetration portion 5T overlaps the penetration portion 14T. Thus, the inorganic insulating layer 111 is exposed from the inorganic insulating layer 5 in the penetration portion 5T.

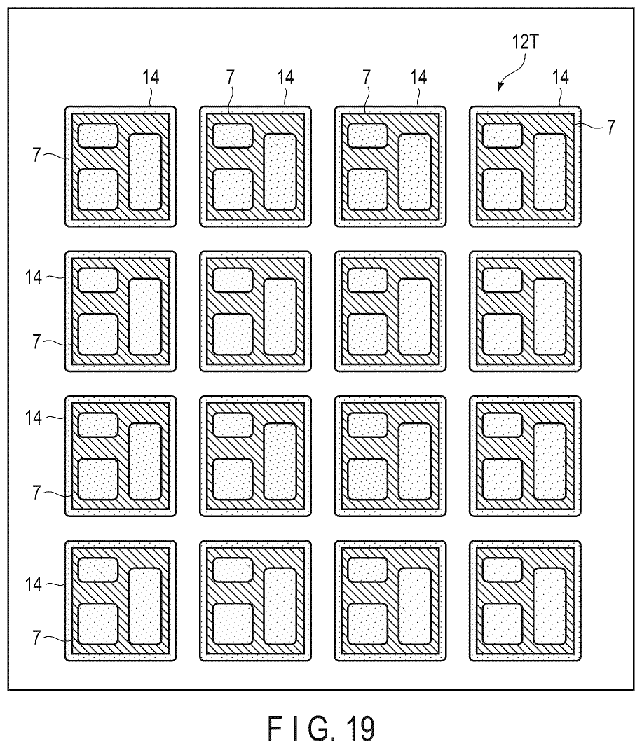

FIG. 19 is a plan view showing another configuration example of the surrounding partitions 7 in the penetration portion 12T.

The configuration example shown in FIG. 19 is different from that shown in FIG. 16 in respect that the sealing layer 14 is divided into pieces more finely. In the example shown in the figure, each portion into which the sealing layer 14 is divided is formed so as to cover one surrounding partition 7. In the sealing layer 14, the portions which cover the surrounding partitions 7, respectively, are spaced apart from each other. Between the adjacent portions of the sealing layer 14, as shown in FIG. 17, the inorganic insulating layer 5 is exposed from the sealing layer 14. Alternatively, between the adjacent portions of the sealing layer 14, as shown in FIG. 18, the inorganic insulating layer 111 is exposed from the sealing layer 14 and the inorganic insulating layer 5.

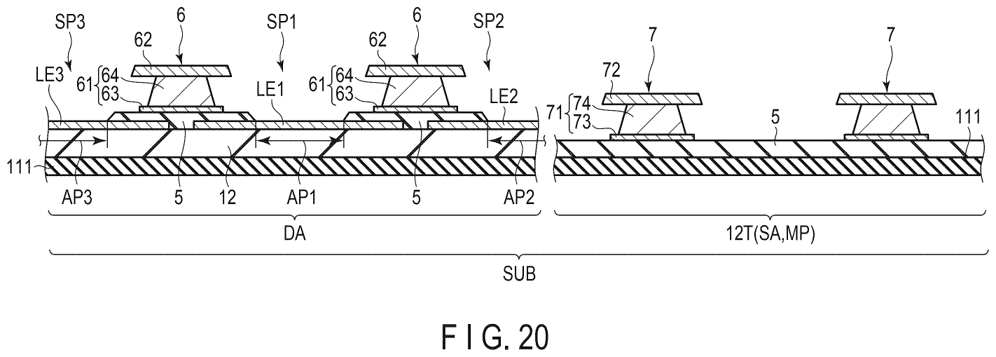

Now, this specification explains the manufacturing method of the display device DSP. Regarding each figure for explaining the manufacturing method, the illustration of the lower side of the inorganic insulating layer 111 is omitted. In FIG. 20 to FIG. 27 referred to in the following explanation, a section corresponding to the left display area DA corresponds to the section taken along the A-B line of FIG. 2, and a section corresponding to the right penetration portion 12T corresponds to the section taken along the I-J line of FIG. 16.

First, as shown in FIG. 20, a processing substrate SUB comprising the lower electrodes LE1, LE2 and LE3, the inorganic insulating layer 5, the partition 6 and the surrounding partitions 7 is prepared. The process of preparing the processing substrate SUB includes the following processes.

Specifically, the circuit layer 11 which includes the inorganic insulating layer 111 is formed over the display area DA, the surrounding area SA and the margin portion MP on the substrate 10. Subsequently, the insulating layer 12 is formed on the inorganic insulating layer 111. In the patterning which is performed when the insulating layer 12 is formed, the penetration portion 12T is formed at the necessary positions of the surrounding area SA and the margin portion MP. By this process, the insulating layer 12 which overlaps the display area DA and the dam portions DM are formed.

Subsequently, the lower electrode LE1 of subpixel SP1, the lower electrode LE2 of subpixel SP2 and the lower electrode LE3 of subpixel SP3 are formed on the insulating layer 12 in the display area DA.

Subsequently, the inorganic insulating layer 5 is formed over the display area DA, the surrounding area SA and the margin portion MP. The inorganic insulating layer 5 covers the peripheral portion of each of the lower electrodes LE1, LE2 and LE3 and has the apertures AP1, AP2 and AP3 which cover the lower electrodes LE1, LE2 and LE3, respectively. In the penetration portion 12T, the inorganic insulating layer 5 is formed on the inorganic insulating layer 111. The inorganic insulating layer 5 is formed of, for example, silicon oxynitride.

Subsequently, the partition 6 which has the lower portion 61 located on the inorganic insulating layer 5 and the upper portion 62 located on the lower portion 61 is formed. At the same time as the formation of the partition 6, the surrounding partitions 7 each of which has the lower portion 71 located on the inorganic insulating layer 5 and the upper portion 72 located on the lower portion 71 is formed in the penetration portion 12T. The bottom layer 63 of the lower portion 61 and the upper portion 62 protrude from the side surfaces of the stem layer 64 of the lower portion 61. Similarly, the bottom layer 73 of the lower portion 71 and the upper portion 72 protrude from the side surfaces of the stem layer 74 of the lower portion 71. Each of the bottom layers 63 and 73 is formed of a titanium-based material, and each of the stem layers 64 and 74 is formed of an aluminum-based material.

It should be noted that the process of forming the apertures AP1, AP2 and AP3 in the inorganic insulating layer 5 may be performed either before the partition 6 and the surrounding partitions 7 are formed or after the partition 6 and the surrounding partitions 7 are formed.

Subsequently, the display element DE1 is formed.

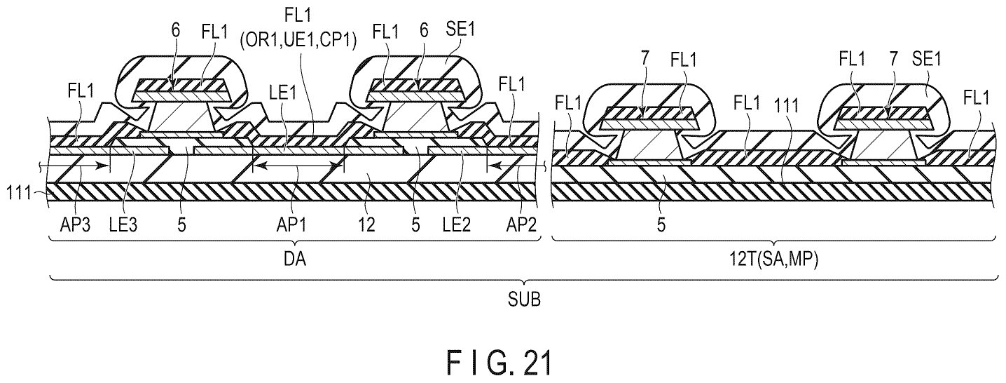

First, as shown in FIG. 21, the stacked film FL1 including the organic layer OR1, the upper electrode UE1 and the cap layer CP1 is formed. The process of forming the stacked film FL1 includes the process of forming the organic layer OR1 on the lower electrode LE1 in the aperture AP1, the process of forming the upper electrode UE1 which covers the organic layer OR1 and is in contact with the lower portion 61 of the partition 6, and the process of forming the cap layer CP1 on the upper electrode UE1. The process of forming the organic layer OR1 includes the process of forming each of the hole injection layer, the hole transport layer, the electron blocking layer, the light emitting layer EM1, the hole blocking layer, the electron transport layer, the electron injection layer and the like. The upper electrode UE1 is formed of a mixture of magnesium and silver.

Each of the organic layer OR1, the upper electrode UE1 and the cap layer CP1 is formed by vapor deposition using the partition 6 as a mask. These organic layer OR1, upper electrode UE1 and cap layer CP1 are continuously formed while maintaining a vacuum environment.

The stacked film FL1 is formed on the lower electrode LE2 and the lower electrode LE3 as well in the display area DA, and is also formed in the surrounding area SA and the margin portion MP. This stacked film FL1 is divided into a plurality of portions by the partition 6 and the surrounding partitions 7 each having an overhang shape. In particular, the stacked film FL1 is divided into pieces in the surrounding area SA and the margin portion MP as the stacked film FL1 is divided by the surrounding partitions 7. By this configuration, the stress which acts on the stacked film FL1 in the manufacturing process is reduced, and thus, the removal of the stacked film FL1 from the inorganic insulating layer 5 can be prevented.

Subsequently, the sealing layer SE1 is formed on the stacked film FL1 by depositing an inorganic insulating material. The sealing layer SE1 is formed over the display area DA, the surrounding area SA and the margin portion MP by chemical vapor deposition (CVD). The sealing layer SE1 continuously covers the portions into which the stacked film FL1 is divided, the partition 6 and the surrounding partitions 7. The sealing layer SE1 is formed of, for example, silicon nitride.

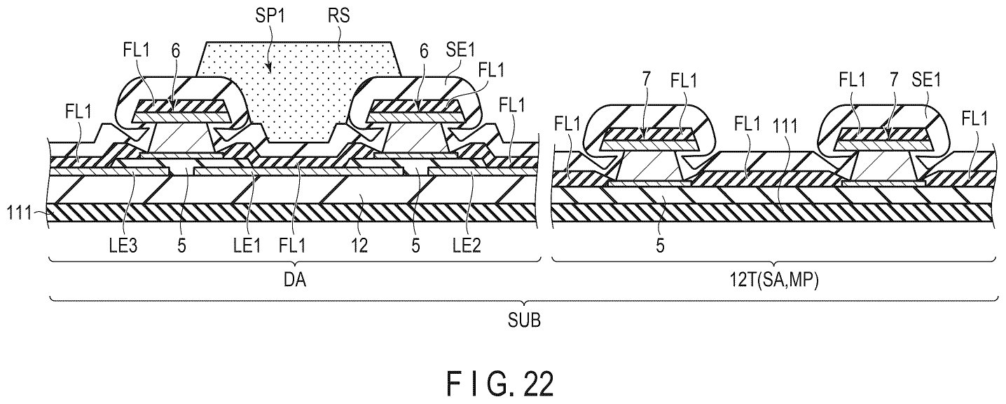

Subsequently, as shown in FIG. 22, a resist RS patterned into a predetermined shape is formed on the sealing layer SE1 in the display area DA. The resist RS overlaps subpixel SP1 and part of the partition 6 around subpixel SP1. The resist RS is not provided in the surrounding area SA or the margin portion MP.

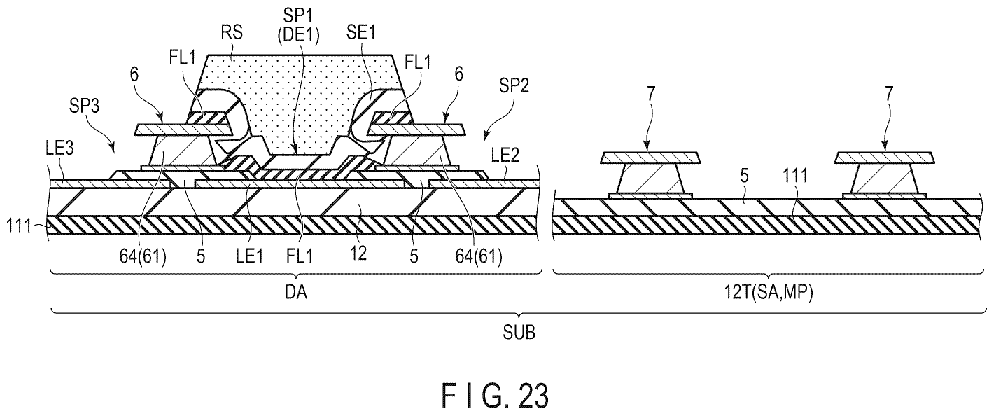

Subsequently, as shown in FIG. 23, etching is performed using the resist RS as a mask to pattern the stacked film FL1 and the sealing layer SE1. Specifically, the sealing layer SE1 exposed from the resist RS is removed by performing dry etching using the resist RS as a mask. Subsequently, the stacked film FL1 exposed from the resist RS is removed. At this time, in the stacked film FL1, the cap layer CP1, the upper electrode UE1 and the organic layer OR1 are removed in this order. By this process, the stacked film FL1 covered with the resist RS remains in subpixel SP1. Further, the upper portion 62 of the partition 6 is partly exposed, and the lower electrode LE2 and the lower electrode LE3 are exposed. Further, the surrounding partitions 7 are exposed in the surrounding area SA and the margin portion MP.

Subsequently, the resist RS is removed. By this process, the display element DE1 is formed in subpixel SP1.

In the process of removing each of the sealing layer SE1 and the stacked film FL1 and further removing the resist RS, the stacked film FL1 located on the upper portion 62 of the partition 6 may be removed in some cases. In these cases, a cavity is formed between the upper portion 62 and the sealing layer SE1.

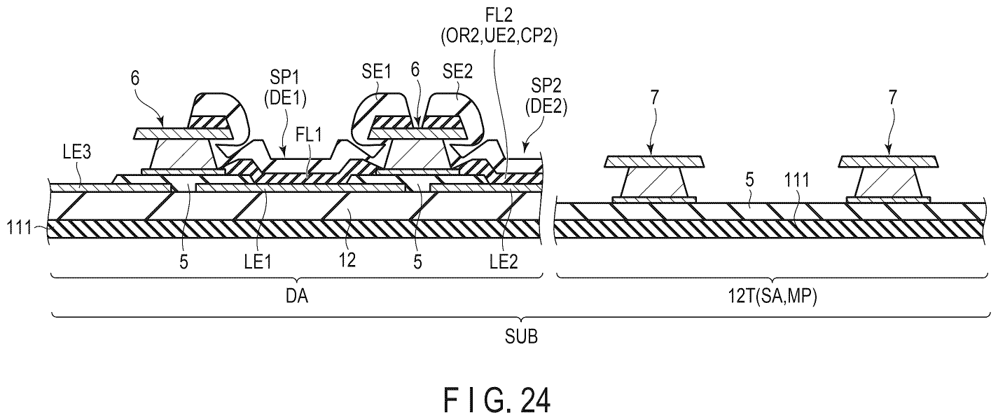

Subsequently, as shown in FIG. 24, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. By this process, the display element DE2 is formed in subpixel SP2, and the lower electrode LE3 of subpixel SP3 is exposed.

It should be noted that, in the process of removing each of the sealing layer SE2 and the stacked film FL2 and further removing the resist, the stacked film FL2 located on the upper portion 62 of the partition 6 may be removed in some cases. In these cases, a cavity is formed between the upper portion 62 and the sealing layer SE2.

The stacked film FL2 does not remain on the surrounding partitions 7, and the surrounding partitions 7 are not covered with the sealing layer SE2.

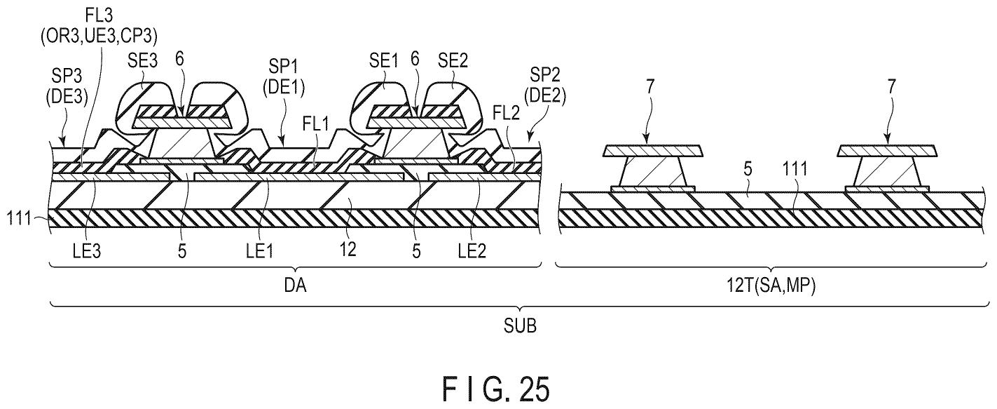

Subsequently, the display element DE3 is formed as shown in FIG. 25. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

It should be noted that, in the process of removing each of the sealing layer SE3 and the stacked film FL3 and further removing the resist, the stacked film FL3 located on the upper portion 62 of the partition 6 may be removed in some cases. In these cases, a cavity is formed between the upper portion 62 and the sealing layer SE3.

The stacked film FL3 does not remain on the surrounding partitions 7, and the surrounding partitions 7 are not covered with the sealing layer SE3.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

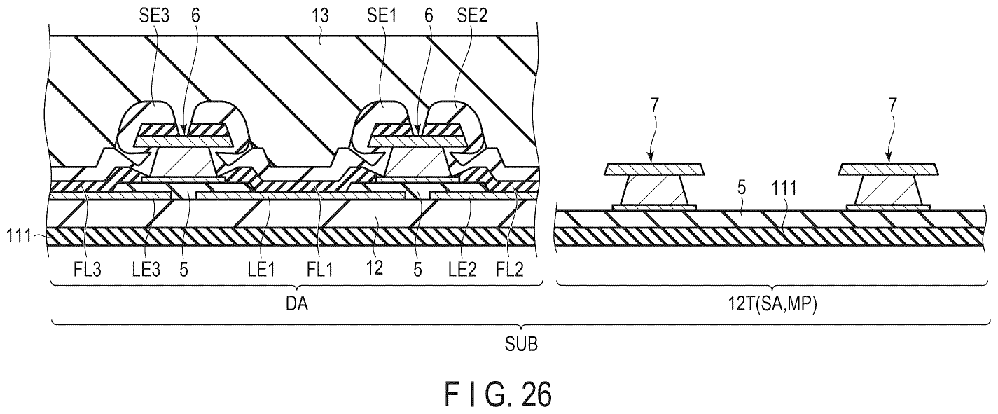

Subsequently, as shown in FIG. 26, the resin layer 13 located on the sealing layers SE1, SE2 and SE3 is formed in the display area DA. When the resinous material for forming the resin layer 13 is applied, the resinous material is dammed up by the dam portions DM shown in FIG. 9 etc., and is not provided in the penetration portion 12T shown in the figure.

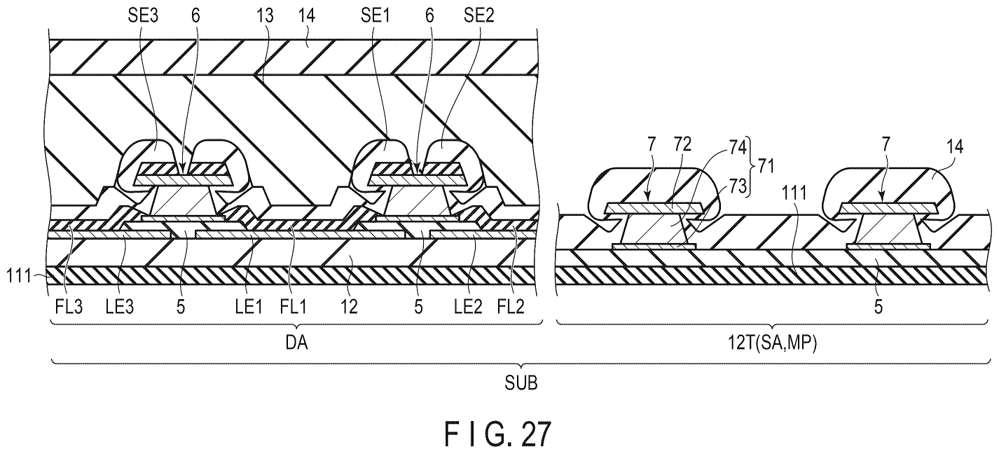

Subsequently, as shown in FIG. 27, the sealing layer 14 is formed by depositing an inorganic insulating material. The sealing layer 14 is formed over the display area DA, the surrounding area SA and the margin portion MP by CVD. The sealing layer 14 is provided on the resin layer 13 in the display area DA and continuously covers the surrounding partitions 7 in the surrounding area SA and the margin portion MP. In other words, the bottom layer 73 and the stem layer 74 of the lower portion 71 and the upper portion 72 are directly covered with the sealing layer 14. The sealing layer 14 is formed of, for example, silicon nitride.

Subsequently, the inorganic insulating layer 5 and the sealing layer 14 are patterned in a lump.

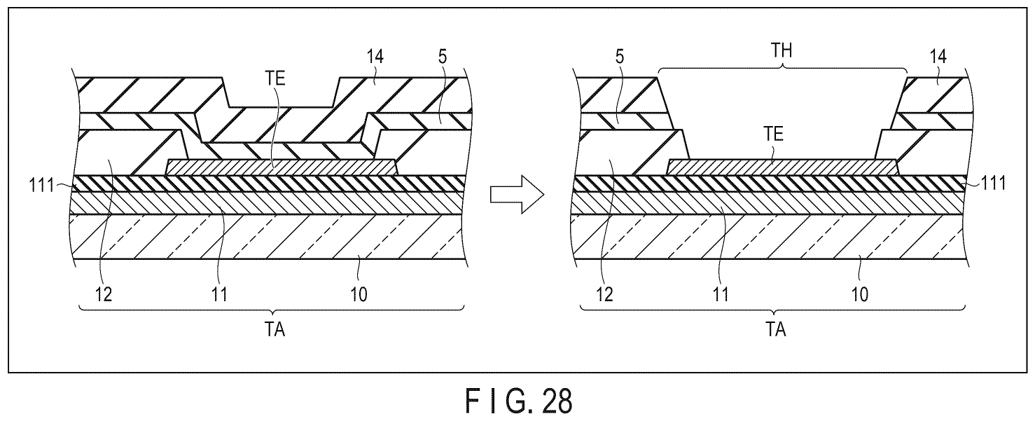

FIG. 28 is a cross-sectional view showing the terminal area TA.

Here, the figure shows the terminal area TA which is part of the surrounding area SA.

As shown on the left side of FIG. 28, the terminal TE is formed in the process of forming the circuit layer 11. For example, the terminal TE is formed on the inorganic insulating layer 111. The insulating layer 12 covers the peripheral portion of the terminal TE. The inorganic insulating layer 5 covers the insulating layer 12 in the terminal area TA and further covers the terminal TE. As explained with reference to FIG. 27, the sealing layer 14 is formed in the surrounding area SA as well and covers the inorganic insulating layer 5 in the terminal area TA.

Subsequently, as shown on the right side of FIG. 28, the inorganic insulating layer 5 and the sealing layer 14 are patterned in a lump, and in the terminal area TA, a through hole TH which penetrates the inorganic insulating layer 5 and the sealing layer 14 is formed, and the terminal TE is exposed. The penetration portions 5T and 14T explained with reference to FIG. 12, FIG. 13, FIG. 15 and FIG. 18 may be formed by the lump patterning of the inorganic insulating layer 5 and the sealing layer 14 explained here. By this process, the inorganic insulating layer 5 and the sealing layer 14 are divided into pieces by the penetration portion 5T and the penetration portion 14T in the surrounding area SA and the margin portion MP.

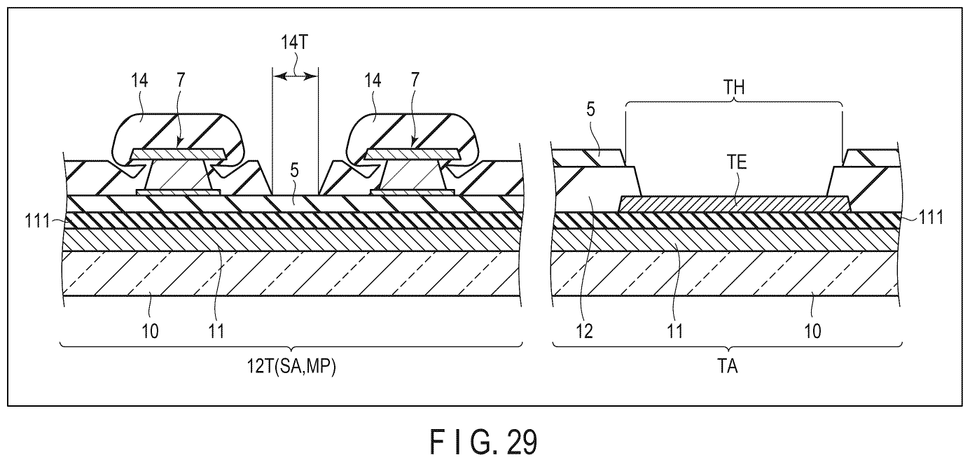

Subsequently, as shown in FIG. 29, the sealing layer 14 is patterned.

In the terminal area TA, the sealing layer 14 located around the terminal TE is removed, and thus, the step in the through hole TH is eased. The penetration portion 14T explained with reference to FIG. 11, FIG. 14 and FIG. 17 may be formed by the patterning of the sealing layer 14 explained here. On the left side of FIG. 29, the penetration portion 14T which is the same as FIG. 17 is shown. In this manner, the sealing layer 14 is divided into pieces by the penetration portion 14T in the surrounding area SA and the margin portion MP.

In other words, the penetration portion 14T may be formed by the lump patterning of the inorganic insulating layer 5 and the sealing layer 14 explained with reference to FIG. 28 or may be formed by the patterning of the sealing layer 14 explained with reference to FIG. 29.

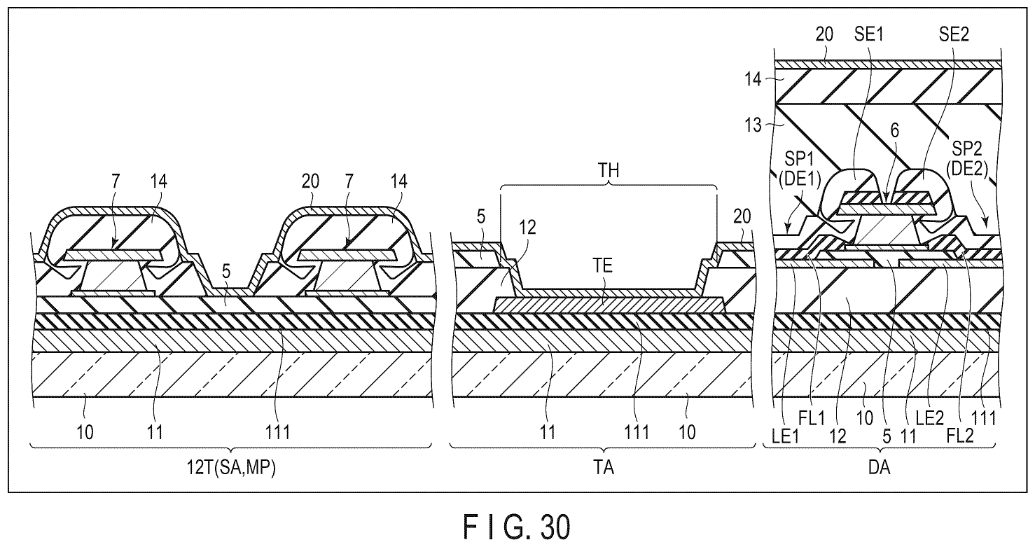

Subsequently, a conductive layer 20 is formed as shown in FIG. 30. The conductive layer 20 is, for example, a multilayer body in which a titanium layer, an aluminum layer and a titanium layer are stacked in order. In the surrounding area SA and the margin portion MP, the conductive layer 20 is provided on the sealing layer 14, and is also provided on the inorganic insulating layer 5. In the terminal area TA, the conductive layer 20 is provided on the inorganic insulating layer 5 and is also provided on the terminal TE in the through hole TH. In the display area DA, the conductive layer 20 is provided on the sealing layer 14.

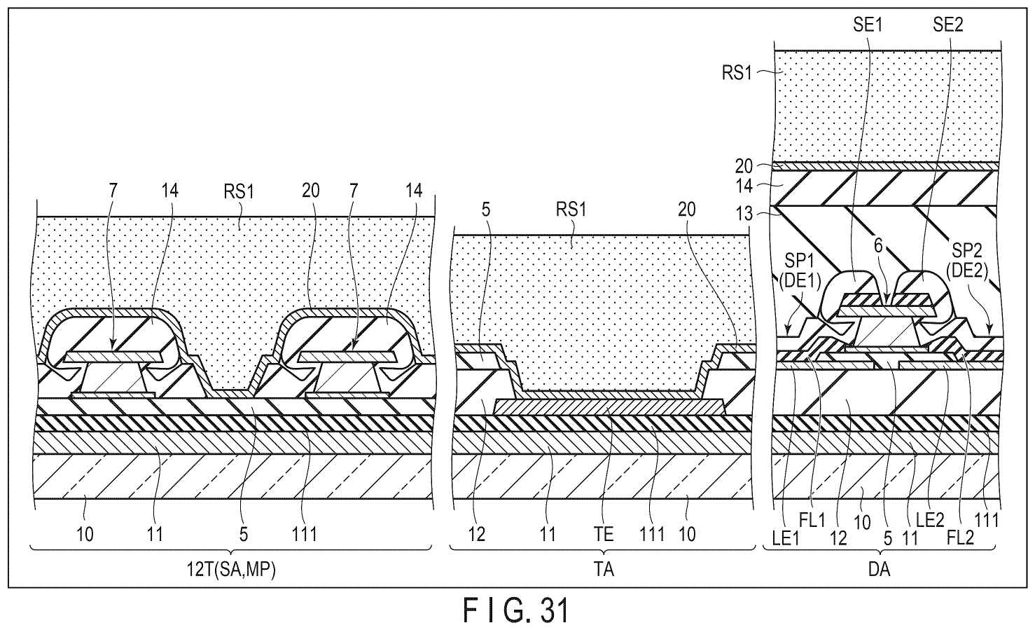

Subsequently, as shown in FIG. 31, a resist RS1 is applied to the upper side of the conductive layer 20. At this time, the unevenness of the surrounding partitions 7 is eased by the sealing layer 14 near the surrounding partitions 7 in the surrounding area SA and the margin portion MP. Therefore, the formation of an undesired void is prevented between the resist RS1 and the surrounding partitions 7. In addition, the surface of the resist RS1 can be planarized. Therefore, in the resist RS1, the formation of an area which is locally thick or an area which becomes the shadow of the surrounding areas 7 is prevented. This resist RS1 is, for example, a positive resist which exhibits solubility for a developer when light is applied.

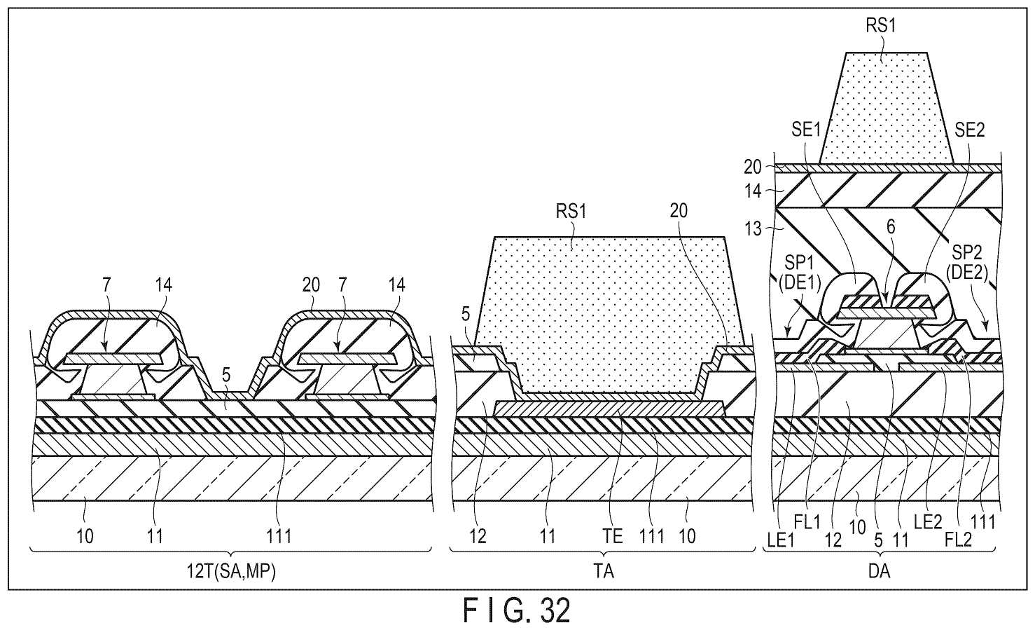

Subsequently, as shown in FIG. 32, the resist RS1 is patterned. By this patterning, the resist RS1 is formed so as to overlap the terminal TE in the terminal area TA, and further, is formed so as to overlap the partition 6 in the display area DA. In the surrounding area SA and the margin portion MP, as almost the entire resist RS1 is exposed to light, the residue of the resist RS1 is not generated.

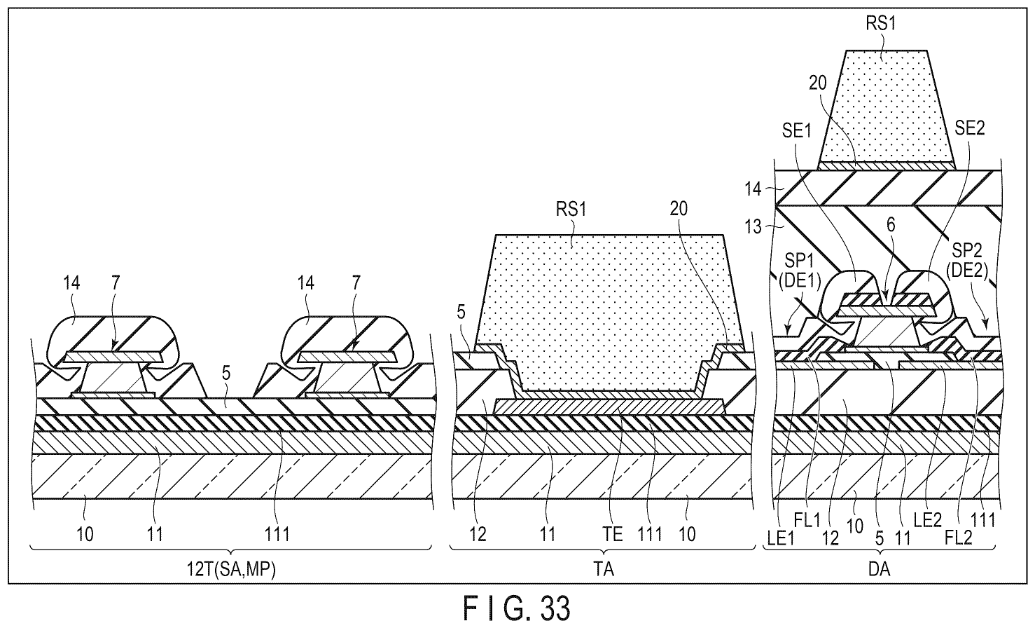

Subsequently, as shown in FIG. 33, the conductive layer 20 is patterned using the resist RS1 as a mask. In the surrounding area SA and the margin portion MP, as the resist RS1 is removed, the residue of the conductive layer 20 is not generated. The conductive layer 20 exposed from the resist RS1 is removed in the terminal area TA and the display area DA.

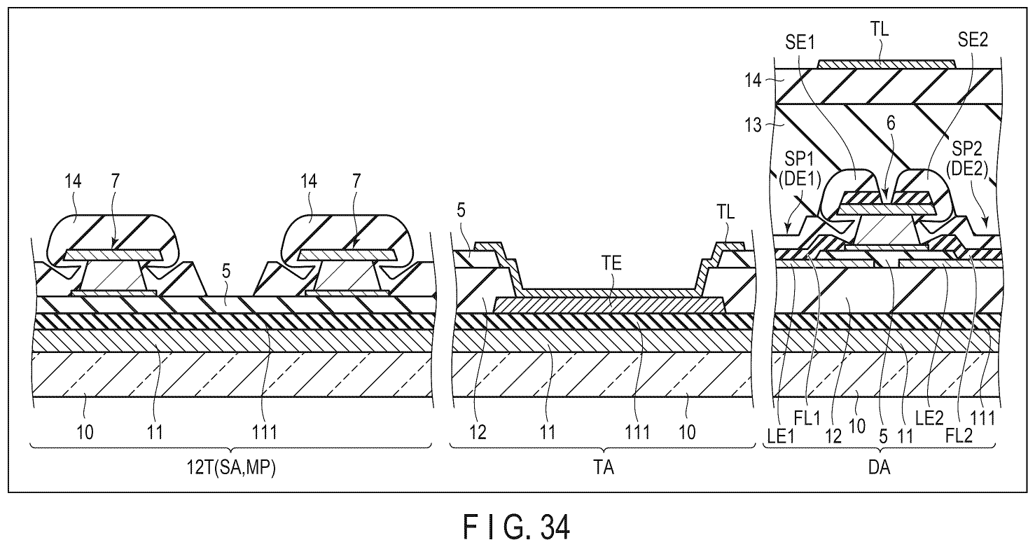

Subsequently, as shown in FIG. 34, the resist RS1 is removed. By this process, the wiring line TL is formed over the display area DA and the terminal area TA, and the wiring line TL is connected to the terminal TE in the terminal area TA.

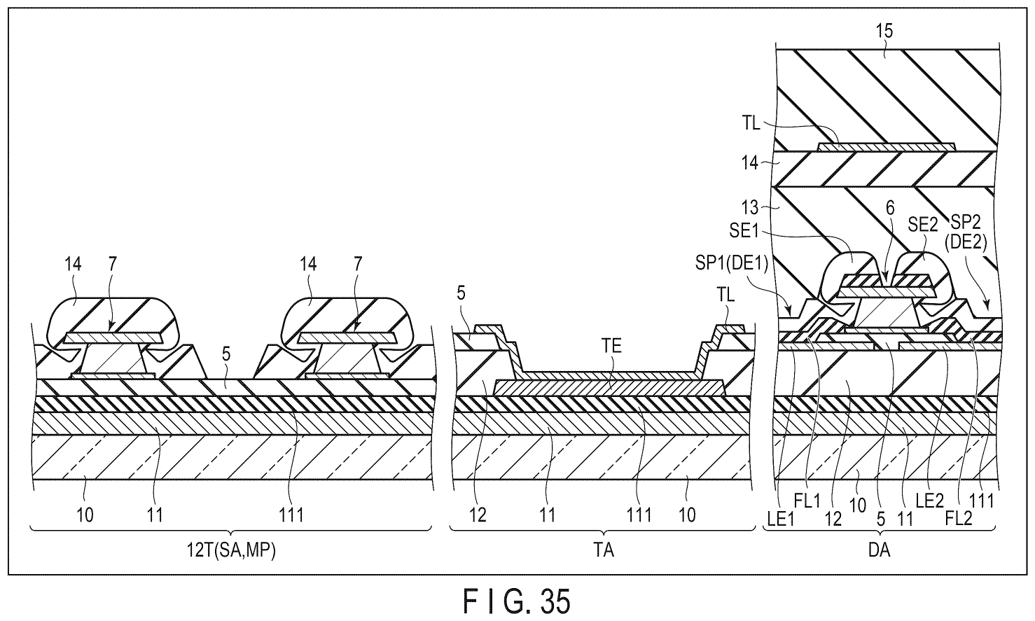

Subsequently, as shown in FIG. 35, the resin layer 15 located on the sealing layer 14 and the wiring line TL is formed in the display area DA. When the resinous material for forming the resin layer 15 is applied, the resinous material is dammed up by the dam portions DM shown in FIG. 9 etc. Thus, the resin layer 15 is not provided in the terminal area TA, surrounding area SA or margin portion MP shown in the figure.

Since the surrounding partitions 7 are covered with the sealing layer 14 as described above, the surrounding partitions 7 are protected by the sealing layer 14 when the conductive layer 20 is patterned in the process of forming the wiring line TL. This configuration prevents undesired scraping of the surrounding partitions 7. In addition, the configuration prevents the generation of conductive particles caused by the removal of part of the surrounding partitions 7.

Further, when the conducive layer 20 is patterned, the configuration prevents the formation of a void between the resist RS1 and the surrounding partitions 7 and the local increase in the film thickness of the resist RS1. Thus, the generation of an undesired residue of the resist RS1 is prevented around the surrounding partitions 7. In this manner, the generation of an undesired residue of the conductive layer 20 is prevented.

Here, the resist RS1 which is applied when the conductive layer 20 is patterned is particularly described. However, regarding the patterning of the inorganic insulating layer 5 and the sealing layer 14 explained with reference to FIG. 28 and the patterning of the sealing layer 14 explained with reference to FIG. 29, similarly, the formation of a void or the local increase in the film thickness of the resist is prevented when the resist is applied. Thus, the generation of an undesired residue of the resist is prevented.

As explained above, the embodiment can provide a display device, a mother substrate for a display device and a manufacturing method of a display device such that the reduction in reliability can be prevented.

In the above embodiment, for example, each of the sealing layers SE1, SE2 and SE3 corresponds to the first sealing layer, and the sealing layer 14 corresponds to the second sealing layer. The resin layer 13 corresponds to the first resin layer, and the resin layer 15 corresponds to the second resin layer. In each of the surrounding partitions 7, the lower portion 71 corresponds to the first lower portion. The upper portion 72 corresponds to the second upper portion. The bottom layer 73 corresponds to the first bottom layer. The stem layer 74 corresponds to the first stem layer. The surrounding partition 7A corresponds to the first surrounding partition. The surrounding partition 7B corresponds to the second surrounding partition. In the partition 6, the lower portion 61 corresponds to the second lower portion. The upper portion 62 corresponds to the second upper portion. The bottom layer 63 corresponds to the second bottom layer. The stem layer 64 corresponds to the second stem layer.

The inorganic insulating layer 111 corresponds to the first inorganic insulating layer. The inorganic insulating layer 5 corresponds to the second inorganic insulating layer. The penetration portion 12T corresponds to the first penetration portion. The penetration portion 14T corresponds to the second penetration portion. The penetration portion 5T corresponds to the third penetration portion.

All of the display devices, mother substrates and manufacturing methods that can be implemented by a person of ordinary skill in the art through arbitrary design changes to the display device, mother substrate and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

An example of the manufacturing method of the display device obtained from the configuration disclosed in this specification is additionally described below.

(1)

A manufacturing method of a display device, the method comprising:
preparing a processing substrate comprising:
   a first inorganic insulating layer over a display area which displays an image and a surrounding area located on an external side relative to the display area;
   an organic insulating layer located on the first inorganic insulating layer;
   a second inorganic insulating layer located on the organic insulating layer;
   a display element located in the display area;
   a plurality of surrounding partitions located in the surrounding area; and
   a first sealing layer which covers the display element and is formed such that the surrounding partitions are exposed; and
forming a second sealing layer over the display area and the surrounding area by an inorganic insulating material, wherein
patterning for forming the organic insulating layer includes a process of forming a first penetration portion in the surrounding area, and
each of the surrounding partitions has a first lower portion provided in the first penetration portion and a first upper portion provided on the first lower portion, and is covered with the second sealing layer.
   (2)

The manufacturing method of (1), wherein
further, after the second sealing layer is formed,
the second inorganic insulating layer and the second sealing layer are patterned in a lump, and
the second sealing layer is patterned.
   (3)

The manufacturing method of (2), wherein
in the lump patterning of the second inorganic insulating layer and the second sealing layer or the patterning of the second sealing layer, a second penetration portion is formed in the second sealing layer located in the surrounding area.
   (4)

The manufacturing method of (2), wherein
the patterning for forming the organic insulating layer includes a process of forming a dam portion located on the first inorganic insulating layer and having a loop shape which surrounds the organic insulating layer, and
in the patterning of the second sealing layer, a second penetration portion which penetrates the second sealing layer is formed at a position overlapping a slope of the dam portion.
   (5)

The manufacturing method of (2), wherein
the patterning for forming the organic insulating layer includes a process of forming a dam portion located on the first inorganic insulating layer and having a loop shape which surrounds the organic insulating layer, and
in the lump patterning of the second inorganic insulating layer and the second sealing layer, a second penetration portion which penetrates the second sealing layer is formed at a position overlapping a slope of the dam portion, and further, a third penetration portion which penetrates the second inorganic insulating layer and is formed such that the slope is exposed is formed at a position overlapping the second penetration portion.
   (6)

The manufacturing method of (1), wherein
further, after the second sealing layer is formed,
a conductive layer is formed,
a resist is formed on the conductive layer, and
a wiring line located on the second sealing layer in the display area and drawn to the surrounding area is formed by patterning the conductive layer using the resist as a mask.

What is claimed is:

1. A display device comprising:
a substrate;
a first inorganic insulating layer provided over a display area which displays an image and a surrounding area located on an external side relative to the display area above the substrate;
an organic insulating layer provided on the first inorganic insulating layer;
a second inorganic insulating layer provided on the organic insulating layer;
a display element provided in the display area;
a first sealing layer which is formed of an inorganic insulating material and covers the display element;
a plurality of surrounding partitions provided in the surrounding area; and
a second sealing layer formed of an inorganic insulating material and provided over the display area and the surrounding area, wherein
the organic insulating layer has a first penetration portion in the surrounding area, and
each of the surrounding partitions has a first lower portion provided in the first penetration portion and a first upper portion provided on the first lower portion, and is covered with the second sealing layer.

2. The display device of claim 1, wherein
the first penetration portion is formed into a loop shape along an end portion of the substrate, and
the second inorganic insulating layer is in contact with the first inorganic insulating layer in the first penetration portion.

3. The display device of claim 1, further comprising a metal layer provided on the first inorganic insulating layer, wherein
the first penetration portion overlaps the metal layer, and
the second inorganic insulating layer is in contact with the metal layer in the first penetration portion.

4. The display device of claim 1, wherein
the second sealing layer has a second penetration portion in the surrounding area.

5. The display device of claim 4, wherein
the second penetration portion is formed into a loop shape which surrounds the display area in plan view.

6. The display device of claim 5, further comprising
a dam portion provided on the first inorganic insulating layer and formed into a loop shape which surrounds the organic insulating layer, wherein
the second penetration portion overlaps a slope of the dam portion.

7. The display device of claim 6, wherein
the second inorganic insulating layer has a third penetration portion overlapping the second penetration portion, and is formed such that the slop is exposed.

8. The display device of claim 1, further comprising:
a first resin layer provided between the first sealing layer and the second sealing layer in the display area; and
a second resin layer provided on the second sealing layer in the display area, wherein
the second sealing layer has a second penetration portion and is in contact with the second inorganic insulating layer in the first penetration portion between the second penetration portion and the display area.

9. The display device of claim 1, wherein
the surrounding partitions include a first surrounding partition, and a second surrounding partition spaced apart from the first surrounding partition, and
the second sealing layer has a second penetration portion between a portion which covers the first surrounding partition and a portion which covers the second surrounding partition.

10. The display device of claim 1, further comprising
a wiring line provided on the second sealing layer in the display area and drawn to the surrounding area.

11. The display device of claim 1, wherein
the first lower portion has a first bottom layer provided on the second inorganic insulating layer, and a first stem layer provided between the first bottom layer and the first upper portion,
the first bottom layer and the first upper portion protrude from a side surface of the first stem layer, and
the second sealing layer is in contact with the first bottom layer, the first stem layer and the first upper portion.

12. The display device of claim 11, further comprising a partition which surrounds the display element, wherein
the partition has a conductive second lower portion provided on the second inorganic insulating layer, and a second upper portion provided on the second lower portion,
the second lower portion has a second bottom layer provided on the second inorganic insulating layer and formed of a same material as the first bottom layer, and a second stem layer provided between the second bottom layer and the second upper portion and formed of a same material as the first stem layer,
the second bottom layer and the second upper portion protrude from a side surface of the second stem layer, and
the first sealing layer is in contact with the second stem layer and the second upper portion.

13. A mother substrate comprising:
a panel portion which has a display area displaying an image, and a surrounding area located on an external side relative to the display area;
a margin portion located on an external side relative to the panel portion;
a first inorganic insulating layer provided over the panel portion and the margin portion;
an organic insulating layer provided on the first inorganic insulating layer;
a second inorganic insulating layer provided on the organic insulating layer;
a display element provided in the display area;
a first sealing layer which is formed of an inorganic insulating material and covers the display element;
a plurality of surrounding partitions provided in the margin portion; and
a second sealing layer formed of an inorganic insulating material and provided over the panel portion and the margin portion, wherein
the organic insulating layer has a first penetration portion in the margin portion, and
each of the surrounding partitions has a first lower portion provided in the first penetration portion and a first upper portion provided on the first lower portion, and is covered with the second sealing layer.

14. The mother substrate of claim 13, wherein
the first penetration portion is formed into a loop shape which surrounds the panel portion, and
the second inorganic insulating layer is in contact with the first inorganic insulating layer in the first penetration portion.

15. The mother substrate of claim 13, further comprising a metal layer provided on the first inorganic insulating layer, wherein
the first penetration portion overlaps the metal layer, and
the second inorganic insulating layer is in contact with the metal layer in the first penetration portion.

16. The mother substrate of claim 13, wherein
the second sealing layer has a second penetration portion in the surrounding area.

17. The mother substrate of claim 16, wherein
the second penetration portion is formed into a loop shape which surrounds the display area in plan view.

18. The mother substrate of claim 17, further comprising
a dam portion provided on the first inorganic insulating layer and formed into a loop shape which surrounds the organic insulating layer in the panel portion, wherein
the second penetration portion overlaps a slope of the dam portion.

19. The mother substrate of claim 13, further comprising:
a first resin layer provided between the first sealing layer and the second sealing layer in the display area; and
a second resin layer provided on the second sealing layer in the display area, wherein
the second sealing layer has a second penetration portion and is in contact with the second inorganic insulating layer in the first penetration portion between the second penetration portion and the display area.

20. The mother substrate of claim 13, wherein
the surrounding partitions include a first surrounding partition, and a second surrounding partition spaced apart from the first surrounding partition, and
the second sealing layer has a second penetration portion between a portion which covers the first surrounding partition and a portion which covers the second surrounding partition.
